(19) United States
(12) Patent Application Publication
(10) Pub. No.: US 2026/0211332 A1
(43) Pub. Date: Jul. 23, 2026

(54) RESIST UNDERLAYER FILM-FORMING COMPOSITION CONTAINING LONG CHAIN ALKYL GROUP-CONTAINING NOVOLAC

(71) Applicant: NISSAN CHEMICAL CORPORATION, Tokyo (JP)

(72) Inventors: Daigo SAITO, Toyama-shi (JP); Takafumi Endo, Toyama-shi (JP); Ryo Karasawa, Toyama-shi (JP); Rikimaru Sakamoto, Toyama-shi (JP)

(73) Assignee: NISSAN CHEMICAL CORPORATION, Tokyo (JP)

(21) Appl. No.: 19/567,856

(22) Filed: Mar. 16, 2026

Related U.S. Application Data
(63) Continuation of application No. 15/769,525, filed on Oct. 14, 2016, now abandoned.

(30) Foreign Application Priority Data
Oct. 19, 2015 (JP) 2015-205743

(51) Int. Cl. G03F 7/11; C08G 8/10; C08G 12/08; C08G 14/06; C09D 161/06; C09D 161/22; C09D 161/34; G03F 7/09; G03F 7/16; G03F 7/20; H10P 50/00; H10P 76/20; H10P 76/40

(52) U.S. Cl. CPC G03F 7/11; C08G 8/10; C08G 12/08; C08G 14/06; C09D 161/06; C09D 161/22; C09D 161/34; G03F 7/091; G03F 7/094; G03F 7/16; G03F 7/168; G03F 7/2002; G03F 7/2037; H10P 50/692; H10P 50/695; H10P 76/20; H10P 76/2041; H10P 76/405

(57) ABSTRACT

A method for producing a semiconductor substrate coated with a resist underlayer film, the method includes applying a resist underlayer film-forming composition with an enhanced thermal reflow property at the time of baking onto a semiconductor substrate having a difference in level, and baking the applied resist underlayer film-forming composition to form a resist underlayer film having a difference in level of the applied surface between a part having the difference in level of the semiconductor substrate and a part having no difference in level of the semiconductor substrate of 3 nm to 73 nm. The resist underlayer film-forming composition includes a novolac resin obtained by reacting an aromatic compound (A) with an aldehyde (B) having a formyl group bonded to a secondary carbon atom or tertiary carbon atom of a C₂₋₂₆ alkyl group for lowering a glass transition temperature (Tg) of the novolac resin.

This application is a continuation application of U.S. patent application Ser. No. 15/769,525 filed Apr. 19, 2018, which is the U.S. national phase of PCT Application No. PCT/JP2016/080575 filed Oct. 14, 2016, and claims priority from Japanese Patent Application No. 2015-205743 filed Oct. 19, 2015. The entire disclosures of these applications are incorporated herein by reference.

### TECHNICAL FIELD

The present invention relates to a resist underlayer film-forming composition for forming a planarization film on a substrate having a difference in level and a method for producing a planarized laminated substrate formed by using a resist underlayer film formed from the resist underlayer film-forming composition.

### BACKGROUND ART

Conventionally, microfabrication has been carried out by lithography using a photoresist composition in the production of semiconductor devices. The microfabrication is a processing method including forming a thin film of a photoresist composition on a substrate to be processed such as a silicon wafer, irradiating the thin film with active light such as ultraviolet rays through a mask pattern in which a pattern of a semiconductor device is depicted, developing the pattern, and etching the substrate to be processed such as a silicon wafer by using the obtained photoresist pattern as a protection film.

In recent years, however, semiconductor devices have been further integrated, and the active light to be used has had a shorter wavelength from a KrF excimer laser (248 nm) to an ArF excimer laser (193 nm). This raises serious problems of the effects of diffused reflection of active light from the substrate and standing waves of the active light.

Consequently, a method for providing an anti-reflective coating between a photoresist and a substrate to be processed has been widely applied. In order to achieve further microfabrication, a lithography technique using extreme ultraviolet rays (EUV, wavelength 13.5 nm) and electron beams (EB) as the active light has been developed. In the EUV lithography or the EB lithography, a specific anti-reflective coating is not required because the diffused reflection from the substrate and the standing wave are not usually generated. The resist underlayer film, however, has begun to be widely studied as an auxiliary film for improving the resolution and adhesion of a resist pattern.

The depth of focus, however, decreases as the exposure wavelength becomes shorter. Consequently, improvement of the planarization property of the film formed on the substrate becomes important in order to form a desired resist pattern with high accuracy. In other words, in order to produce a semiconductor device having a fine design rule, a resist underlayer film that can form a smooth coating surface without a difference in level on the substrate is essential.

For example, a resist underlayer film-forming composition containing a hydroxy group-containing carbazole novolac resin has been described (refer to Patent Document 1).

A resist underlayer film-forming composition containing a diarylamine novolac resin has been also described (refer to Patent Document 2).

A resist underlayer film-forming composition containing a crosslinkable compound having a C₂₋₁₀ alkoxymethyl group and a C₁₋₁₀ alkyl group has been also described (refer to Patent Document 3).

### PRIOR ART DOCUMENTS

### Patent Documents

Patent Document 1: WO 2012/077640 Pamphlet
Patent Document 2: WO 2013/047516 Pamphlet
Patent Document 3: WO 2014/208542 Pamphlet

### SUMMARY OF THE INVENTION

### Problem to be Solved by the Invention

For the resist underlayer film-forming composition, a coating film is thermally cured by introducing a self-crosslinking moiety into a polymer resin being a main component or adequately adding a crosslinking agent, a crosslinking catalyst, and the like to the resist underlayer film-forming composition and baking the resultant resist underlayer film-forming composition at high temperature in order not to cause mixing when a photoresist composition or a different resist underlayer film is laminated. By this process, the photoresist composition or the different resist underlayer film can be laminated without mixing. Such a thermosetting resist underlayer film-forming composition, however, contains a polymer having a thermally crosslinkable functional group such as hydroxy group, a crosslinking agent, and an acid catalyst (acid generator) and thus viscosity is increased when the crosslinking reaction by baking proceeds at the time of filling the resist underlayer film-forming composition into the pattern (for example, a hole or a trench structure) formed on a substrate. Consequently, the planarizing property after film formation tends to deteriorate due to worsening the filling ability into the pattern.

An object of the present invention is to improve the filling ability into the pattern during baking by enhancing a thermal reflow property of the polymer. In other words, in order to enhance the thermal reflow property of the polymer, the object of the present invention is to provide a resist underlayer film-forming composition for forming a coating film having a high planarizing property on the substrate, in which a sufficient reduction in viscosity can be achieved before starting the crosslinking reaction at the time of the baking by introducing a linear or branched long chain alkyl group that can decrease the grass transition temperature of the polymer.

### Means for Solving the Problem

The present invention includes, as a first aspect, a resist underlayer film-forming composition comprising: a novolac resin obtained by reacting an aromatic compound (A) with an aldehyde (B) having formyl group bonded to a secondary carbon atom or tertiary carbon atom of a C₂₋₂₆ alkyl group,
as a second aspect, the resist underlayer film-forming composition according to the first aspect, in which the novolac resin comprises a unit structure of Formula (1):

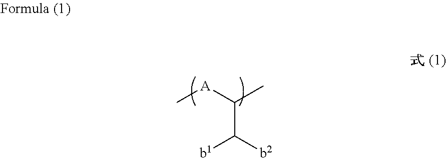

(in Formula (1), A is a bivalence group derived from a C₆₋₄₀ aromatic compound; b¹ is a C₁₋₁₆ alkyl group; and b² is a hydrogen atom or a C₁₋₉ alkyl group);
as a third aspect, the resist underlayer film-forming composition according to the second aspect, in which A is the bivalent group derived from an aromatic compound comprising an amino group, a hydroxy group, or both an amino group and a hydroxy group,
as a fourth aspect, the resist underlayer film-forming composition according to the second aspect, in which A is the bivalent group derived from an aromatic compound comprising an arylamine compound, a phenol compound, or both an arylamine compound and a phenol compound,
as a fifth aspect, the resist underlayer film-forming composition according to the second aspect, in which A is the bivalent group derived from aniline, diphenylamine, phenylnaphthylamine, hydroxydiphenylamine, carbazole, phenol, N,N′-diphenylethylenediamine, N,N′-diphenyl-1,4-phenylenediamine, or a polynuclear phenol,
as a sixth aspect, the resist underlayer film-forming composition according to the fifth aspect, in which the polynuclear phenol is dihydroxybenzene, trihydroxybenzene, hydroxynaphthalene, dihydroxynaphthalene, trihydroxynaphthalene, tris(4-hydroxyphenyl) methane, tris(4-hydroxyphenyl) ethane, 2,2′-biphenol, or 1,1,2,2-tetrakis (4-hydroxyphenyl) ethane,
as a seventh aspect, the resist underlayer film-forming composition according to the first aspect, in which the novolac resin is a novolac resin comprising a unit structure of 5 Formula (2):

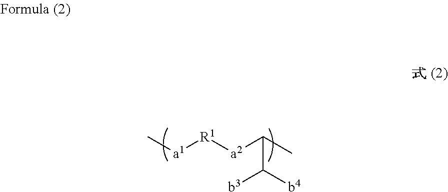

(in Formula (2), each a¹ and a² is an optionally substituted benzene ring or naphthalene ring; and R¹ is a secondary amino group or a tertiary amino group, an optionally substituted C₁₋₁₀ divalent hydrocarbon group, an arylene group, or a divalent group to which these groups are arbitrarily bonded; b³ is a C₁₋₁₆ alkyl group, and b⁴ is a hydrogen atom or a C₁₋₉ alkyl group),
as an eight aspect, the resist underlayer film-forming composition according to any one of the first aspect to the seventh aspect, further comprising an acid and/or an acid generator,
as a ninth aspect, the resist underlayer film-forming composition according to any one of the first aspect to the eighth aspect, further comprising a crosslinking agent,
as a tenth aspect, a method for forming a resist underlayer film, the method comprising:
applying the resist underlayer film-forming composition according to any one of the first aspect to the ninth aspect onto a semiconductor substrate having a difference in level and baking the applied resist underlayer film-forming composition to form a resist underlayer film having a difference in level of the applied surface between a part having the difference in level of the substrate and a part having no difference in level of the substrate of 3 nm to 73 nm,
as an eleventh aspect, a method for forming a resist pattern used in production of semiconductors, the method comprising:
applying the resist underlayer film-forming composition according to any one of the first aspect to the ninth aspect onto a semiconductor substrate and baking the applied resist underlayer film-forming composition to form an underlayer film,
as a twelfth aspect, a method for producing a semiconductor device, the method comprising:
forming an underlayer film from the resist underlayer film-forming composition according to any one of the first aspect to the ninth aspect on a semiconductor substrate;
forming a resist film on the underlayer film;
forming a resist pattern by irradiation with light or electron beams and development;
etching the underlayer film by using the formed resist pattern; and
processing the semiconductor substrate by using the patterned underlayer film,
as a thirteenth aspect, a method for producing a semiconductor device, the method comprising:
forming an underlayer film from the resist underlayer film-forming composition according to any one of the first aspect to the ninth aspect on a semiconductor substrate;
forming a hard mask on the underlayer film;
further forming a resist film on the hard mask;
forming a resist pattern by irradiation with light or electron beams and development;
etching the hard mask by using the formed resist pattern;
etching the underlayer film by using the patterned hard mask; and
processing the semiconductor substrate by using the patterned underlayer film, and
as a fourteenth aspect, the method for producing a semiconductor device according to the thirteenth aspect, in which the hard mask is formed by vapor deposition of an inorganic substance.

### Effects of the Invention

The resist underlayer film-forming composition of the present invention has an enhanced thermal reflow property at the time of baking obtained by introducing a long chain alkyl group, which acts for lowering the grass transition temperature (Tg) of a polymer, into the skeleton of the main resin in the resist underlayer film-forming composition. Therefore, filling ability of the resist underlayer film-forming composition into the pattern on the substrate can be improved due to the high thermal reflow property of the polymer when the resist underlayer film-forming composition of the present invention is applied onto the substrate and the applied composition is baked. In addition, the resist underlayer film-forming composition of the present invention can form a smooth film on the substrate regardless of an open area (non-patterned area) and a patterned area of DENSE (dense) and ISO (sparse) on the substrate. Therefore, the resist underlayer film-forming composition of the present invention can simultaneously satisfy both the filling performance into the pattern and planarizing performance after filling and thus can form an excellent planarization film.

The underlayer film formed form the resist underlayer film-forming composition of the present invention has an adequate anti-reflective effect and also has a high dry etching rate compared with the resist film. This high dry etching rate enables the substrate to be processed.

### MODES FOR CARRYING OUT THE INVENTION

The present invention includes a resist underlayer film-forming composition comprising: a novolac resin obtained by reacting an aromatic compound (A) with an aldehyde (B) having formyl group bonded to a secondary carbon atom or tertiary carbon atom of a C₂₋₂₆ or C₂₋₁₉ alkyl group.

In the present invention, the resist underlayer film-forming composition for lithography includes the resin and a solvent. The resist underlayer film-forming composition may also include a crosslinking agent, an acid, an acid generator, a surfactant, and the like, if necessary.

The solid content of this composition is 0.1% by mass to 70% by mass or 0.1% by mass to 60% by mass. The solid content is a content ratio of the whole components of the resist underlayer film-forming composition from which the solvent is removed. In the solid content, the polymer can be contained in a ratio of 1% by mass to 100% by mass, 1% by mass to 99.9% by mass, 50% by mass to 99.9% by mass, 50% by mass to 95% by mass, or 50% by mass to 90% by mass.

The polymer used in the present invention has a weight average molecular weight of 500 to 1,000,000 or 600 to 200,000.

The novolac resin used in the present invention can include the unit structure of Formula (1).

In Formula (1), A is a bivalent group derived from a C₆₋₄₀ aromatic compound. b¹ is a C₁₋₁₆ or C₁₋₉ alkyl group and b² is a hydrogen atom or a C₁₋₉ alkyl group. The novolac resin may have a branched alkyl group, in which both b¹ and b² are C₁₋₁₆ or C₁₋₉ alkyl groups or may have a linier alkyl group, in which b¹ is a C₁₋₁₆ or C₁₋₉ alkyl group and b² is a hydrogen atom.

A can be a bivalent group derived from an aromatic compound comprising an amino group, a hydroxy group, or both an amino group and a hydroxy group. In addition, A can be the bivalent group derived from an aromatic compound comprising an arylamine compound, a phenol compound, or both an arylamine compound and a phenol compound. More specifically, A is the bivalent group derived from aniline, diphenylamine, phenylnaphthylamine, hydroxydiphenylamine, carbazole, phenol, N,N′-diphenylethylenediamine, N,N′-diphenyl-1,4-phenylenediamine, or a polynuclear phenol.

Examples of the polynuclear phenol include dihydroxybenzene, trihydroxybenzene, hydroxynaphthalene, dihydroxynaphthalene, trihydroxynaphthalene, tris (4-hydroxyphenyl) methane, tris(4-hydroxyphenyl) ethane, 2,2′-biphenol, or 1,1,2,2-tetrakis (4-hydroxyphenyl) ethane.

The novolac resin can include a unit structure of Formula (2) that is a more specific example of the unit structure of Formula (1). The characteristics of the unit structure of Formula (1) are reflected to the unit structure of Formula (2).

The novolac resin having the unit structure of Formula (2) can be obtained by reacting an aromatic compound (A) corresponding to a (a¹-R¹-a²) part in Formula (2) with an aldehyde (B) having formyl group bonded to a tertiary carbon atom.

Examples of the aromatic compound (A) corresponding to the (a¹-R¹-a²) part include diphenylamine, phenylnaphthylamine, hydroxydiphenylamine, tris(4-hydroxyphenyl) ethane, N,N′-diphenylethylenediamine, 2,2′-biphenol, and N,N′-diphenyl-1,4-phenylenediamine.

In Formula (2), each a¹ and a² is an optionally substituted benzene ring or naphthalene ring; and R¹ is a secondary amino group or a tertiary amino group, an optionally substituted C₁₋₁₀, C₁₋₆, or C₁₋₂ divalent hydrocarbon group, an arylene group, or a divalent group to which these groups are arbitrarily bonded. Examples of the arylene group include organic groups such as phenylene group and naphthylene group. In a¹ and a², hydroxy group can be exemplified as a substituent.

b³ is a C₁₋₁₆ or C₁₋₉ alkyl group and b⁴ is a hydrogen atom or a C₁₋₉ alkyl group. The novolac resin may have a branched alkyl group when both b³ and b⁴ are C₁₋₁₆ or C₁₋₉ alkyl groups or may have a linier alkyl group when b³ is a C₁₋₁₆ or C₁₋₉ alkyl group and b⁴ is a hydrogen atom.

In Formula (2), examples of R¹ include a secondary amino group and a tertiary amino group. When R¹ is the tertiary amino group, R¹ has a structure in which the alkyl group is substituted. Among these amino groups, the secondary amino group can be preferably used.

In Formula (2), examples of the optionally substituted C₁₋₁₀ or C₁₋₆ or C₁₋₂ bivalent hydrocarbon group in the definition of R¹ include methylene group or ethylene group. Examples of the substituent include phenyl group, naphthyl group, hydroxyphenyl group, and hydroxynaphthyl group.

In Formulas, examples of the C₁₋₁₆ or C₁₋₉ alkyl group include methyl group, ethyl group, n-propyl group, i-propyl group, cyclopropyl group, n-butyl group, i-butyl group, s-butyl group, t-butyl group, cyclobutyl group, 1-methyl-cyclopropyl group, 2-methyl-cyclopropyl group, n-pentyl group, 1-methyl-n-butyl group, 2-methyl-n-butyl group, 3-methyl-n-butyl group, 1,1-dimethyl-n-propyl group, 1,2-dimethyl-n-propyl group, 2,2-dimethyl-n-propyl, 1-ethyl-n-propyl group, cyclopentyl group, 1-methyl-cyclobutyl group, 2-methyl-cyclobutyl group, 3-methyl-cyclobutyl group, 1,2-dimethyl-cyclopropyl group, 2,3-dimethyl-cyclopropyl group, 1-ethyl-cyclopropyl group, 2-ethyl-cyclopropyl group, n-hexyl group, 1-methyl-n-pentyl group, 2-methyl-n-pentyl group, 3-methyl-n-pentyl group, 4-methyl-n-pentyl group, 1,1-dimethyl-n-butyl group, 1,2-dimethyl-n-butyl group, 1,3-dimethyl-n-butyl group, 2,2-dimethyl-n-butyl group, 2,3-dimethyl-n-butyl group, 3,3-dimethyl-n-butyl group, 1-ethyl-n-butyl group, 2-ethyl-n-butyl group, 1,1,2-trimethyl-n-propyl group, 1,2,2-trimethyl-n-propyl group, 1-ethyl-1-methyl-n-propyl group, 1-ethyl-2-methyl-n-propyl group, n-hexyl group, n-heptyl group, n-octyl group, n-nonyl group, n-tridecanyl group, and n-hexadecanyl group.

In Formulas, examples of the C₁₋₁₆ or C₁₋₉ alkyl group include the alkyl groups exemplified above. In particular, examples of the C₁₋₁₆ or C₁₋₉ alkyl group include methyl group, ethyl group, n-propyl group, i-propyl group, n-butyl group, i-butyl group, s-butyl group, and t-butyl group. These groups may be used in combination.

The aldehyde (B) used in the present invention can be exemplified as follows.

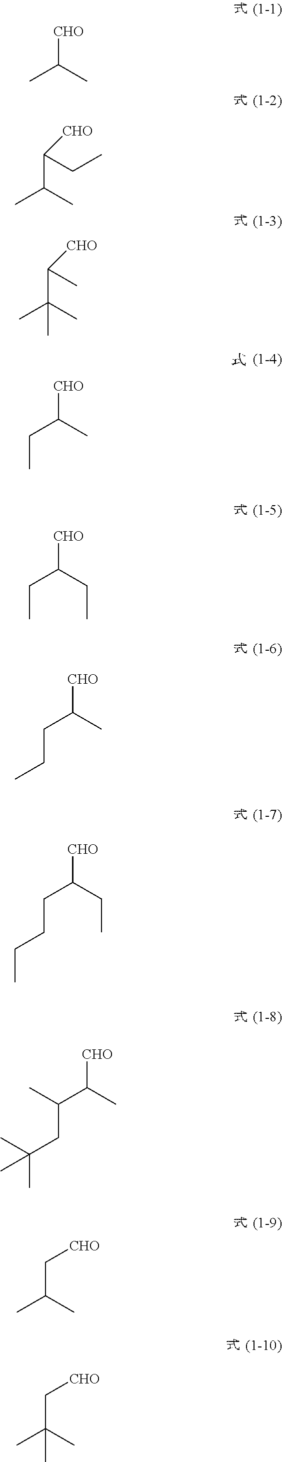

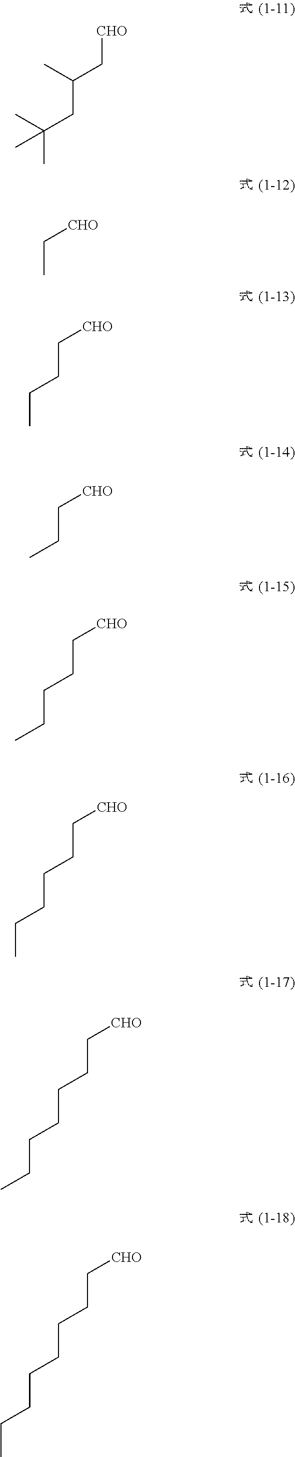

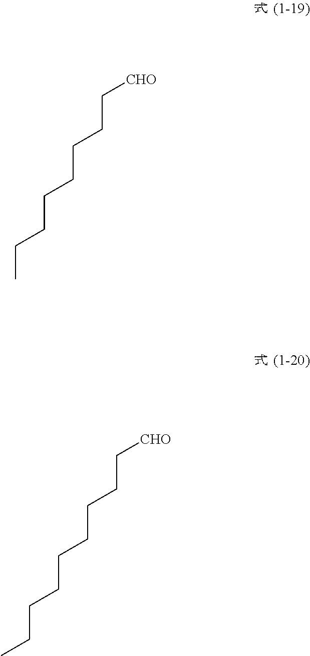

In the reaction of the aromatic compound (A) and the aldehyde (B), A and B are preferably reacted in a molar ratio of 1:0.5 to 2.0 or 1:1.

Examples of the acid catalyst used in the condensation reaction include mineral acids such as sulfuric acid, phosphoric acid, and perchloric acid; organic sulfonic acids such as p-toluenesulfonic acid, p-toluenesulfonic acid monohydrate, methanesulfonic acid and trifluoromethanesulfonic acid; and carboxylic acids such as formic acid and oxalic acid. The amount of the acid catalyst to be used is selected depending on the type of the acid catalyst to be used. The amount is usually 0.001 part by mass to 10,000 parts by mass, preferably 0.01 part by mass to 1,000 parts by mass, and more preferably 0.1 part by mass to 100 parts by mass relative to 100 parts by mass of the organic compound A including an aromatic ring.

The condensation reaction may be carried out without solvent. The condensation reaction, however, is usually carried out with solvent. All of the solvents can be used as long as the solvents do not inhibit the reaction. Examples of the solvent include ethers such as 1,2-dimethoxyethane, diethylene glycol dimethyl ether, propylene glycol monomethyl ether, propylene glycol monomethyl ether acetate, butyl cellosolve, tetrahydrofuran (THF), and dioxane. When the acid catalyst to be used is a liquid acid such as formic acid, the acid can also act as the solvent.

The reaction temperature at the time of condensation is usually 40° C. to 200° C. The reaction time is variously selected depending on the reaction temperature and usually about 30 minutes to about 50 hours.

The weight average molecular weight Mw of thus obtained polymer is usually 500 to 1,000,000 or 600 to 200,000.

Examples of the novolac resin obtained by reacting the aromatic compound (A) with the aldehyde (B) include novolac resins having the following unit structures.

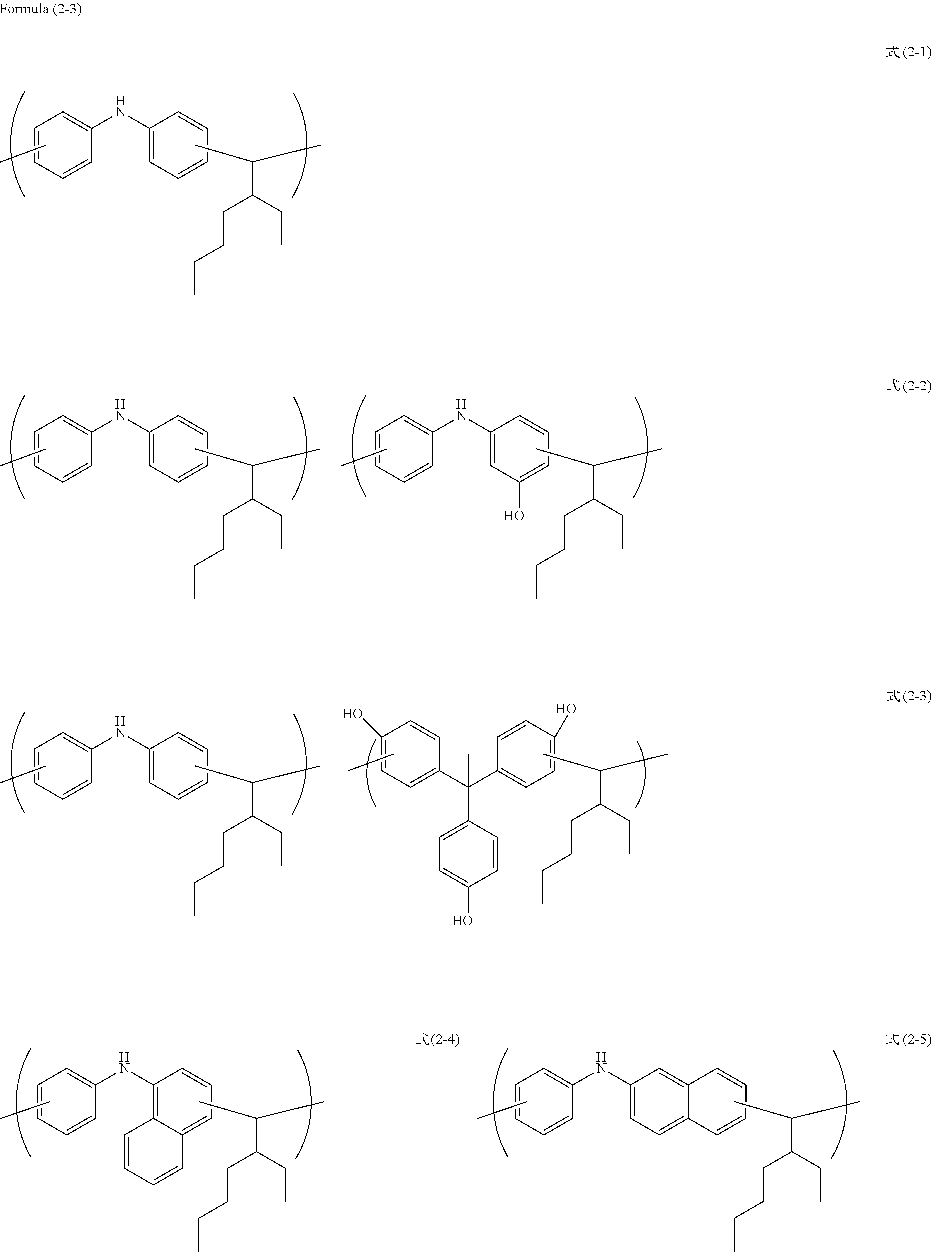

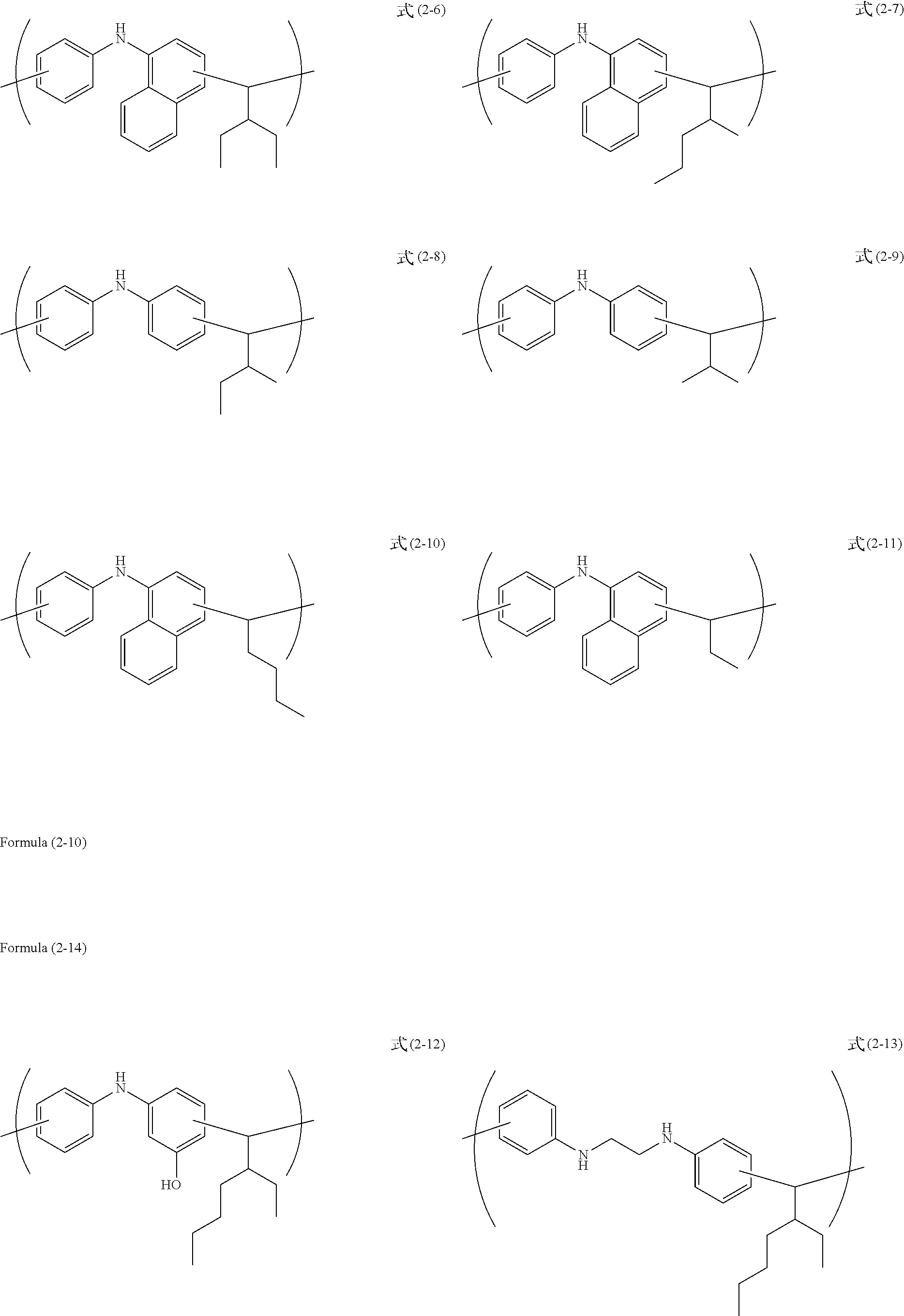

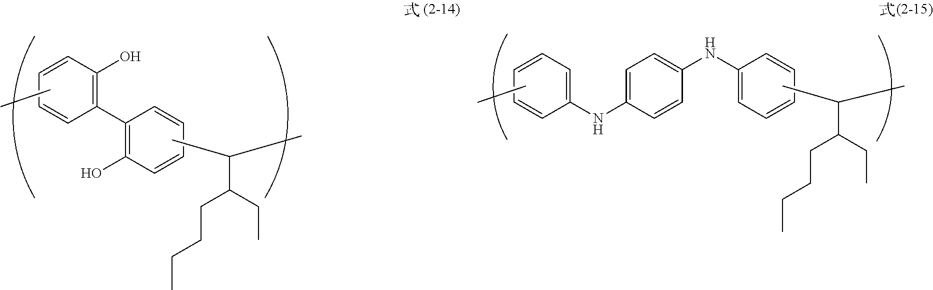

The resist underlayer film-forming composition of the present invention may include a crosslinking agent component. Examples of the crosslinking agent may include a melamine-based agent, a substituted urea-based agent, or a polymer-based agent thereof. Preferably, the crosslinking agent has at least two crosslink-forming substituents. Examples of the crosslinking agent include compounds such as methoxymethylated glycoluril, butoxymethylated glycoluril, methoxymethylated melamine, butoxymethylated melamine, methoxymethylated benzoguanamine, butoxymethylated benzoguanamine, methoxymethylated urea, butoxymethylated urea, methoxymethylated thiourea, or methoxymethylated thiourea. Condensates of these compounds can also be used.

As the crosslinking agent, a crosslinking agent having high heat resistance can be used. As the crosslinking agent having high heat resistance, a compound containing crosslink-forming substituents having aromatic rings (for example, benzene rings or naphthalene rings) in its molecule can preferably be used.

Examples of these compounds include compounds having a partial structure of Formula (3) and a polymer or oligomer having a repeating unit of Formula (4).

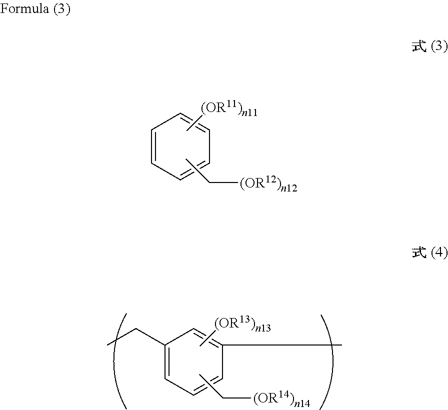

R¹¹, R¹², R¹³, and R¹⁴ are hydrogen atoms or C₁₋₁₀ alkyl groups and the alkyl groups exemplified above can be used as these C₁₋₁₀ alkyl groups.
n11 is an integer satisfying 1≤n11≤6−n12, n12 is an integer satisfying 1≤n12≤5, n13 is an integer satisfying 1≤n13≤4−n14, and n14 is an integer satisfying 1≤n14≤3.

The compounds, polymers, and oligomers of Formula (3) and Formula (4) are exemplified as follows. The sign “Me” is methyl group.

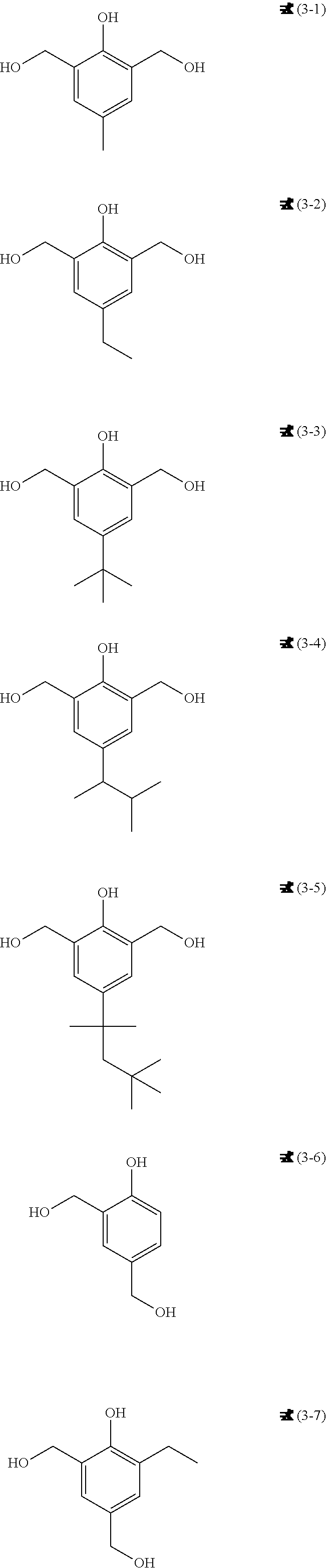

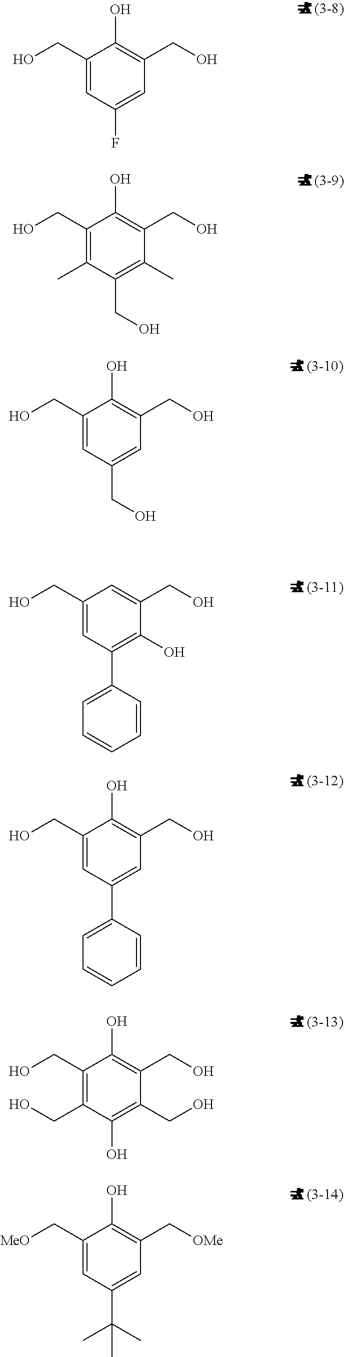

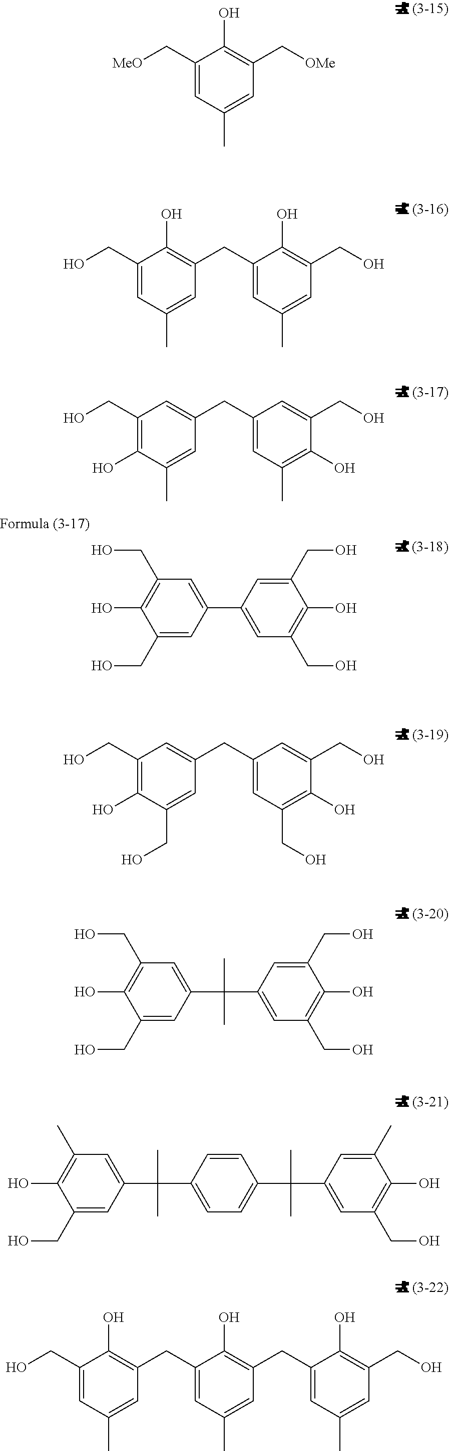

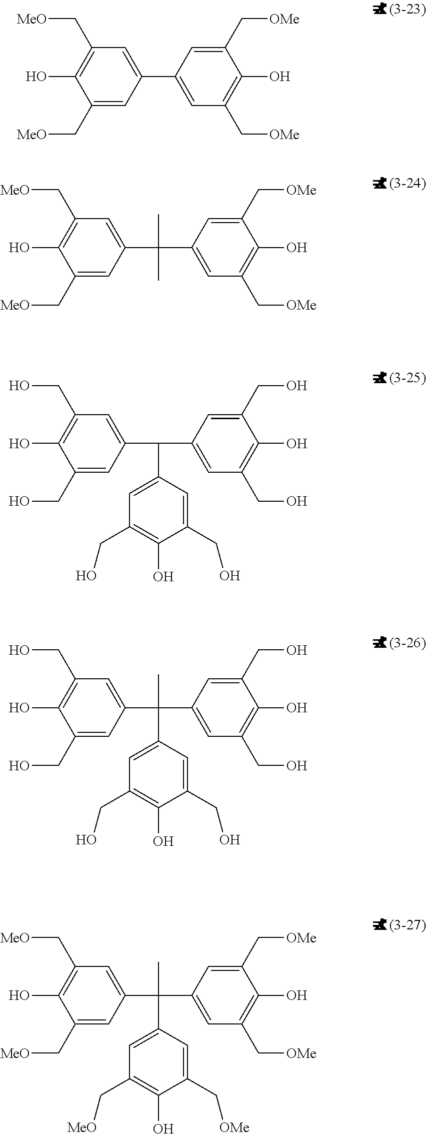 [SMILES: COCc1cc(-c2cc(COC)c(O)c(COC)c2)cc(COC)c1O ; COCc1cc(C(C)(C)c2cc(COC)c(O)c(COC)c2)cc(COC)c1O ; OCc1cc(C(c2cc(CO)c(O)c(CO)c2)c2cc(CO)c(O)c(CO)c2)cc(CO)c1O ; CC(c1cc(CO)c(O)c(CO)c1)(c1cc(CO)c(O)c(CO)c1)c1cc(CO)c(O)c(CO)c1 ; COCc1cc(C(C)(c2cc(COC)c(O)c(COC)c2)c2cc(COC)c(O)c(COC)c2)cc(COC)c1O]

Formula (3-26) the compounds can be obtained as commercial products manufactured by Asahi Organic Chemicals Industry Co., Ltd. and HONSHU CHEMICAL INDUSTRY CO., LTD. For example, among the crosslinking agent, the compound of Formula (3-24) can be obtained as TM-BIP-A (trade name, manufactured by Asahi Organic Chemicals Industry Co., Ltd.).

The amount of the crosslinking agent to be added varies depending on an application solvent to be used, a base substrate to be used, a required solution viscosity, a required film shape, and the like. The amount is 0.001% by mass to 80% by mass, preferably 0.01% by mass to 50% by mass, and further preferably 0.05% by mass to 40% by mass relative to the whole solid content. These crosslinking agents may cause a crosslinking reaction by self-condensation. The crosslinking agent can, however, cause a crosslinking reaction with a crosslinkable substituent when the crosslinkable substituent exists in the polymer of the present invention.

In the present invention, acidic compounds such as p-toluenesulfonic acid, trifluoromethanesulfonic acid, pyridinium p-toluenesulfonate, salicylic acid, 5-sulfosalicylic acid, 4-phenolsulfonic acid, pyridinium 4-phenolsulfonate, camphorsulfonic acid, 4-chlorobenzenesulfonic acid, benzenedisulfonic acid, 1-naphthalenesulfonic acid, citric acid, benzoic acid, hydroxybenzoic acid, naphthalene carboxylic acid and/or thermal acid generators such as 2,4,4,6-tetrabromocyclohexadienone, benzoin tosylate, 2-nitrobenzyl tosylate, and other organic sulfonic acid alkyl esters can be added as a catalyst for promoting the crosslinking reaction. The amount of the catalyst to be added is 0.0001% by mass to 20% by mass, preferably 0.0005% by mass to 10% by mass, and further preferably 0.01% by mass to 3% by mass relative to the whole solid content.

In order to match the acidity of the resist underlayer film-forming composition to the acidity of the photoresist that covers the resist underlayer film in the lithography process as an upper layer, the resist underlayer film-forming composition for lithography of the present invention can contain a photoacid generator. Examples of the preferable photoacid generator include an onium salt photoacid generators such as bis(4-t-butylphenyl) iodonium trifluoromethanesulfonate and triphenylsulfonium trifluoromethanesulfonate; halogen-containing compound photoacid generators such as phenyl-bis(trichloromethyl)-s-triazine; and sulfonic acid photoacid generators such as benzoin tosylate and N-hydroxysuccinimide trifluoromethanesulfonate. The amount of the photoacid generator is 0.2% by mass to 10% by mass and preferably 0.4% by mass to 5% by mass relative to the whole solid content.

To the resist underlayer film composition for lithography of the present invention, for example, a further light absorbent, a rheology modifier, an adhesion assistance agent, or a surfactant can be added in addition to the components described above if necessary.

As further light absorbents, for example, commercially available light absorbents described in “Kogyoyo Shikiso no Gijutsu to Shijyo (Technology and Market of Industrial Colorant)” (CMC Publishing Co., Ltd) and “Senryo Binran (Dye Handbook)” (The Society of Synthetic Organic Chemistry, Japan) can be preferably used. Preferably useable examples of the commercially available light absorbents include C. I. Disperse Yellow 1, 3, 4, 5, 7, 8, 13, 23, 31, 49, 50, 51, 54, 60, 64, 66, 68, 79, 82, 88, 90, 93, 102, 114, and 124; C. I. Disperse Orange 1, 5, 13, 25, 29, 30, 31, 44, 57, 72, and 73; C. I. Disperse Red 1, 5, 7, 13, 17, 19, 43, 50, 54, 58, 65, 72, 73, 88, 117, 137, 143, 199, and 210; C. I. Disperse Violet 43; C. I. Disperse Blue 96; C. I. Fluorescent Brightening Agent 112, 135, and 163; C. I. Solvent Orange 2 and 45; C. I. Solvent Red 1, 3, 8, 23, 24, 25, 27, and 49; C. I. Pigment Green 10; and C. I. Pigment Brown 2. The light absorbents are usually added in ratio of 10% by mass or lower, and preferably in a ratio of 5% by mass or lower relative to the whole solid content of the resist underlayer film composition for lithography.

The rheology modifier is added for the purpose of mainly improving flowability of the resist underlayer film-forming composition, and, particularly in a baking process, improving film thickness uniformity of the resist underlayer film and enhancing filling ability of the resist underlayer film-forming composition into inside of a hole. Specific examples of the rheology modifier include phthalic acid derivatives such as dimethyl phthalate, diethyl phthalate, diisobutyl phthalate, dihexyl phthalate, and butylisodecyl phthalate, adipic acid derivatives such as di-normal-butyl adipate, diisobutyl adipate, diisooctyl adipate, and octyldecyl adipate, maleic acid derivatives such as di-normal-butylmaleate, diethyl maleate, and dinonyl maleate, oleic acid derivatives such as methyl oleate, butyl oleate, and tetrahydrofurfuryl oleate, or stearic acid derivatives such as normal-butyl stearate, and glyceryl stearate. These rheology modifiers are usually added in a ratio of lower than 30% by mass relative to the whole solid content of the resist underlayer film composition for lithography.

The adhesion assistance agent is mainly added in order to improve adhesion between the substrate or the resist and the resist underlayer film-forming composition and in order to prevent peeling of the resist, particularly in development. Specific examples of the adhesion assistance agent may include chlorosilanes such as trimethylchlorosilane, dimethylvinylchlorosilane, methyldiphenylchlorosilane, and chloromethyldimethylchlorosilane, alkoxysilanes such as trimethylmethoxysilane, dimethyldiethoxysilane, methyldimethoxysilane, dimethylvinylethoxysilane, diphenyldimethoxysilane, and phenyltriethoxysilane, silazanes such as hexamethyldisilazane, N,N′-bis(trimethylsilyl) urea, dimethyltrimethylsilylamine, and trimethylsilylimidazole, silanes such as vinyltrichlorosilane, γ-chloropropyltrimethoxysilane, γ-aminopropyltriethoxysilane, and γ-glycidoxypropyltrimethoxysilane, heterocyclic compounds such as benzotriazole, benzimidazole, indazole, imidazole, 2-mercaptobenzimidazole, 2-mercaptobenzothiazole, 2-mercaptobenzoxazole, urazole, thiouracil, mercaptoimidazole, and mercaptopyrimidine, and urea compounds or thiourea compounds such as 1,1-dimethylurea and 1,3-dimethylurea. These adhesion assistance agents are usually added in a ratio of lower than 5% by mass, and preferably in a ratio of lower than 2% by mass relative to the whole solid content of the resist underlayer film composition for lithography.

To the resist underlayer film composition for lithography of the present invention, a surfactant can be added for preventing generation of pinholes and striations and further improving applicability to surface unevenness. Examples of the surfactant may include nonionic surfactant such as polyoxyethylene alkyl ethers including polyoxyethylene lauryl ethers, polyoxyethylene stearyl ethers, polyoxyethylene cetyl ethers, and polyoxyethylene oleyl ethers; polyoxyethylene alkylallyl ethers including polyoxyethylene octylphenol ethers and polyoxyethylene nonylphenol ethers; polyoxyethylene-polyoxypropylene block copolymers; sorbitan fatty acid esters including sorbitan monolaurate, sorbitan monopalmitate, sorbitan monostearate, sorbitan monooleate, sorbitan trioleate, and sorbitan tristearate; and polyoxyethylene sorbitan fatty acid esters including polyoxyethylene sorbitan monolaurates, polyoxyethylene sorbitan monopalmitates, polyoxyethylene sorbitan monostearates, polyoxyethylene sorbitan trioleates, and polyoxyethylene sorbitan tristearates; fluorochemical surfactants such as EFTOP EF301, EF303, and EF352 (manufactured by Tochem Products, trade name), MEGAFAC F171, F173, and R-30 (manufactured by Dainippon Ink and Chemicals Inc., trade name), Fluorad FC430 and FC431 (manufactured by Sumitomo 3M Ltd., trade name), Asahi guard AG710, Surflon S-382, SC101, SC102, SC103, SC104, SC105, and SC106 (manufactured by Asahi Glass Co., Ltd., trade name); and Organosiloxane Polymer KP341 (manufactured by Shin-Etsu Chemical Co., Ltd.). The amount of the surfactant to be added is usually 2.0% by mass or less and preferably 1.0% by mass or less relative to the whole solid content of the resist underlayer film composition for lithography of the present invention. These surfactants can be added singly or in combination of two or more of them.

In the present invention, usable examples of a solvent dissolving the polymer, the crosslinking agent component, and the crosslinking catalyst include ethylene glycol monomethyl ether, ethylene glycol monoethyl ether, methyl cellosolve acetate, ethyl cellosolve acetate, diethylene glycol monomethyl ether, diethylene glycol monoethyl ether, propylene glycol, propylene glycol monomethyl ether, propylene glycol monomethyl ether acetate, propylene glycol monoethyl ether, propylene glycol monoethyl ether acetate, propylene glycol propyl ether acetate, toluene, xylene, methyl ethyl ketone, cyclopentanone, cyclohexanone, ethyl 2-hydroxypropionate, ethyl 2-hydroxy-2-methylpropionate, ethyl ethoxyacetate, ethyl hydroxyacetate, methyl 2-hydroxy-3-methylbutanoate, methyl 3-methoxypropionate, ethyl 3-methoxypropionate, ethyl 3-ethoxypropionate, methyl 3-ethoxypropionate, methyl pyruvate, ethyl pyruvate, ethyl acetate, butyl acetate, ethyl lactate, and butyl lactate. These organic solvents can be used singly or in combination of two or more of them.

In addition, these solvents can be used by mixing with a high boiling point solvent such as propylene glycol monobutyl ether and propylene glycol monobutyl ether acetate. Among these solvents, propylene glycol monomethyl ether, propylene glycol monomethyl ether acetate, ethyl lactate, butyl lactate, and cyclohexanone are preferable for improving a levering property.

The resist used in the present invention is a photoresist and an electron beam resist.

As the photoresist applied on the resist underlayer film for lithography of the present invention, both a negative photoresist and a positive photoresist can be used. Examples of the resists include a positive photoresist made of a novolac resin and 1,2-naphthoquinonediazidesulfonate, a chemically amplified photoresist made of a binder having a group that increases an alkali dissolution rate by decomposing with an acid and a photoacid generator, a chemically amplified photoresist made of an alkali-soluble binder, a low molecular weight compound that increases an alkali dissolution rate of the photoresist by decomposing with an acid, and a photoacid generator, a chemically amplified photoresist made of a binder having a group that increases an alkali dissolution rate by decomposing with an acid, a low molecular weight compound that increases an alkali dissolution rate of the photoresist by decomposing with an acid, and a photoacid generator, and a photoresist having Si atoms in the skeleton of the molecule of the photoresist. Specific examples may include APEX-E (trade name, manufactured by Rohm and Haas Inc.).

Examples of the electron beam resist applied onto the resist underlayer film for lithography of the present invention include a composition made of a resin containing Si—Si bonds in the main chain and containing aromatic rings at its ends and an acid generator generating an acid by electron beam irradiation and a composition made of poly (p-hydroxystyrene) in which hydroxy groups are substituted with organic groups containing N-carboxyamine and an acid generator generating an acid by electron beam irradiation. In the latter electron beam resist composition, the acid generated from the acid generator by the electron beam irradiation is reacted with the N-carboxyaminoxy groups of the polymer side chain and the polymer side chain is decomposed into hydroxy group to exhibit alkali solubility. Consequently, the resist composition is dissolved into an alkali development liquid to form a resist pattern. Examples of the acid generator generating the acid by electron beam irradiation may include halogenated organic compounds such as 1,1-bis [p-chlorophenyl]-2,2,2-trichloroethane, 1,1-bis [p-methoxyphenyl]-2,2,2-trichloroethane, 1,1-bis [p-chlorophenyl]-2,2-dichloroethane, and 2-chloro-6-(trichloromethyl)pyridine, onium salts such as triphenylsulfonium salts and diphenyliodonium salts, and sulfonic acid esters such as nitrobenzyl tosylate and dinitrobenzyl tosylate.

As the development liquid for the resist having the resist underlayer film formed by using the resist underlayer film composition for lithography of the present invention, the following aqueous alkali solutions can be used. Examples of the aqueous alkali solutions include solutions of inorganic alkalis such as sodium hydroxide, potassium hydroxide, sodium carbonate, sodium silicate, sodium metasilicate, and aqueous ammonia; primary amines such as ethylamine and n-propylamine; secondary amines such as diethylamine and di-n-butylamine; tertiary amines such as triethylamine and methyldiethylamine; alcoholamines such as dimethylethanolamine and triethanolamine; quaternary ammonium salts such as tetramethylammonium hydroxide, tetraethylammonium hydroxide, and choline; and cyclic amines such as pyrrole and piperidine. To the aqueous solutions of the alkalis described above, an adequate amount of alcohols such as isopropyl alcohol or a surfactant such as a nonionic surfactant may be added and the mixture may be used. Among these development liquids, aqueous solutions of the quaternary ammonium salts are preferable and aqueous solutions of tetramethylammonium hydroxide and choline are further preferable.

Subsequently, a method for forming the resist pattern of the present invention will be described. The resist underlayer film-forming composition is applied onto a substrate (for example, transparent substrate such as silicon/silicon dioxide coated glass substrate, and an ITO substrate) used for producing precision integrated circuit elements by an appropriate application method such as a spinner and a coater and thereafter the coated composition is cured by baking to form an application type underlayer film. A film thickness of the resist underlayer film is preferably 0.01 μm to 3.0 μm. Conditions for baking after the application are 80° C. to 400° C. for 0.5 minute to 120 minutes. Thereafter, the resist is directly applied onto the resist underlayer film or applied after forming a film made of one layer or several layers of coating material on the application type underlayer film if necessary. Thereafter, the resist is irradiated with light or electron beams through the predetermined mask and is developed, rinsed, and dried to allow an excellent resist pattern to be obtained. Post Exposure Bake (PEB) of light or electron beams can also be carried out, if necessary. The part of the resist underlayer film where the resist is removed by the previous process is removed by dry etching to allow a desired pattern on the substrate to be formed.

The exposure light of the photoresist is actinic rays such as near ultraviolet rays, far ultraviolet rays, or extreme ultraviolet rays (for example, EUV, wavelength of 13.5 nm) and, for example, light having a wavelength of 248 nm (KrF laser light), 193 nm (ArF laser light), or 157 nm (F2 laser light) is used. The light irradiation can be used without limitation as long as the acid is generated from the photoacid generator. An exposure amount is 1 mJ/cm² to 2,000 mJ/cm², or 10 mJ/cm² to 1,500 mJ/cm², or 50 mJ/cm² to 1,000 mJ/cm².

The electron beam irradiation to the electron beam resist can be carried out by, for example, using an electron beam irradiation device.

In the present invention, a semiconductor device can be produced through steps of forming a resist underlayer film from the resist underlayer film-forming composition on a semiconductor substrate; forming a resist film on the resist underlayer film; forming a resist pattern by irradiation with light or electron beams and development; etching the resist underlayer film by using the formed resist pattern; and processing the semiconductor substrate by using the patterned resist underlayer film.

When the finer resist pattern formation will be progressed in the future, the problem of resolution and the problem of resist pattern collapse after development will occur and thus formation of a thinner resist film will be desired. Consequently, the resist pattern thickness sufficient for substrate processing is difficult to secure. As a result, as the processes, not only the resist pattern but also the resist underlayer film formed between the resist and the semiconductor substrate to be processed has been required to have the function as a mask at the time of the substrate processing. As the resist underlayer film for such a process, a resist underlayer film for lithography having the selectivity of dry etching rate close to that of the resist, a resist underlayer film for lithography having the selectivity of dry etching rate smaller than that of the resist, or a resist underlayer film for lithography having the selectivity of dry etching rate smaller than that of the semiconductor substrate, which is different from conventional resist underlayer films having high etch rate properties, has been required. Such a resist underlayer film can be provided with the function of anti-reflective properties and thus can also have the function of a conventional anti-reflective coating.

On the other hand, in order to obtain a finer resist pattern, a process has been also started to be used in which the resist pattern and the resist underlayer film at the time of resist underlayer film dry etching narrower than the pattern width at the time of resist development are formed. As the resist underlayer film for such a process, the resist underlayer film having the selectivity of dry etching rate close to that of the resist, which is different from conventional high etching rate anti-reflective coatings, has been required. Such a resist underlayer film can be provided with the function of anti-reflective properties and thus can also have the function of a conventional anti-reflective coating.

In the present invention, after the resist underlayer film of the present invention is formed on the substrate, the resist can be applied directly onto the resist underlayer film or after a film made of a single layer or several layers of coating material is formed on the resist underlayer film. This makes the pattern width of the resist narrow. Even when the resist is thinly covered in order to prevent pattern collapse, the substrate can be processed by selecting an appropriate etching gas.

More specifically, the semiconductor device can be manufactured through steps of: forming a resist underlayer film from the resist underlayer film-forming composition on a semiconductor substrate; forming a hard mask on the resist underlayer film using a coating material containing a silicon component and the like or a hard mask (for example, silicon oxynitride) by vapor deposition; forming a resist film on the hard mask; further forming a resist pattern by irradiation with light or electron beams and development; etching the hard mask using the formed resist pattern with a halogen-based gas; etching the resist underlayer film using the patterned hard mask with an oxygen-based gas or a hydrogen-based gas; and processing the semiconductor substrate using the patterned resist underlayer film with the halogen-based gas.

The resist underlayer film-forming composition of the present invention is applied onto the substrate and, when the composition is baked, filled into the pattern formed on the substrate by the thermal reflow of the polymer. In the present invention, the thermal reflow property is enhanced by introducing a long chain alkyl group, which generally acts for lowering the grass transition temperature (Tg) of the polymer, into the skeleton of the main resin in the resist underlayer film-forming composition. This can improve the filling ability of the composition into the pattern. Consequently, the resist underlayer film-forming composition of the present invention can form a smooth film on the substrate regardless of an open area (non-patterned area) and a patterned area of DENSE (dense) and ISO (sparse), whereby the composition can simultaneously satisfy both the filling performance into the pattern and planarizing performance after filling and thus can form an excellent planarization film.

In consideration of the effect as the anti-reflective coating, the resist underlayer film-forming composition for lithography of the present invention includes a light absorption moiety in the skeleton and thus no substances are diffused into the photoresist at the time of drying by heating. The light absorption moiety has sufficiently large light absorption properties and thus has a high anti-reflection effect.

The resist underlayer film-forming composition for lithography of the present invention has high heat stability, prevents contamination to the upper layer film caused by decomposed substances at the time of baking, and can provide an extra temperature margin during the baking process.

Depending on process conditions, the film formed from the resist underlayer film for lithography of the present invention can be used as a film that has the anti-reflection function and further has a functions that prevents interaction between the substrate and the photoresist or prevents adverse effect on the substrate due to the materials used for the photoresist or substances generated at the time of light exposure to the photoresist.

### MODES FOR CARRYING OUT THE INVENTION

### Example 1

To a 100-mL four-necked flask, diphenylamine (14.01 g, 0.083 mol, manufactured by Tokyo Chemical Industry Co., Ltd.), 2-ethylhexyl aldehyde (10.65 g, 0.083 mol, manufactured by Tokyo Chemical Industry Co., Ltd.), and butyl cellosolve (25 g, manufactured by Kanto Chemical Co., Inc.) were fed, added with trifluoromethanesulfonic acid (0.37 g, 0.0025 mol, manufactured by Tokyo Chemical Industry Co., Ltd.) to be stirred together, and were heated to 150° C. to be dissolved, so that polymerization was started. The content of the flask cooled to room temperature 1 hour thereafter, added with THF (10 g, manufactured by Kanto Chemical Co., Inc.) to be diluted, and re-precipitated into methanol (700 g, manufactured by Kanto Chemical Co., Inc.) to obtain precipitate. The obtained precipitate was filtered and dried by a vacuum dryer at 80° C. for 24 hours to obtain 23.0 g of a target polymer (corresponding to formula (2-1), hereinafter abbreviated to pDPA-EHA).

The pDPA-EHA has a weight average molecular weight Mw of 5,200 and a polydispersity Mw/Mn of 2.05, which were measured by GPC in terms of polystyrene. Next, 1.00 g of this obtained novolac resin, 0.25 g of 3,3′,5,5′-tetramethoxymethyl-4,4′-bisphenol (trade name: TMOM-BP, manufactured by HONSHU CHEMICAL INDUSTRY CO., LTD.) as a crosslinking agent, 0.025 g of pyridinium p-phenol sulfonic acid indicated by formula (5) as a crosslinking catalyst, and 0.001 g of a surfactant (manufactured by DIC Corporation, product name: MEGAFAC [trade name] R-30N, a fluorochemical surfactant) were dissolved into 4.42 g of propylene glycol monomethylether and 10.30 g of propylene glycol monomethylether acetate to prepare a resist underlayer film-forming composition.

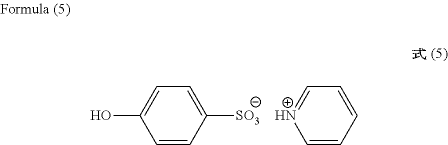

### Example 2

To a 100-mL four-necked flask, diphenylamine (6.82 g, 0.040 mol, manufactured by Tokyo Chemical Industry Co., Ltd.), 3-hydroxydiphenylamine (7.47 g, 0.040 mol), 2-ethylhexyl aldehyde (10.34 g, 0.081 mol, manufactured by Tokyo Chemical Industry Co., Ltd.), and butyl cellosolve (25 g, manufactured by Kanto Chemical Co., Inc.) were fed, added with trifluoromethanesulfonic acid (0.36 g, 0.0024 mol, manufactured by Tokyo Chemical Industry Co., Ltd.) to be stirred together, and were heated to 150° C. to be dissolved, so that polymerization was started. The content of the flask cooled to room temperature 1 hour thereafter, added with THF (20 g, manufactured by Kanto Chemical Co., Inc.) to be diluted, and re-precipitated using a mixed solvent of methanol (500 g, manufactured by Kanto Chemical Co., Inc.), ultrapure water (500 g), and 30% ammonium water (50 g, manufactured by Kanto Chemical Co., Inc.) to obtain precipitate. The obtained precipitate was filtered and dried by a vacuum dryer at 80° C. for 24 hours to obtain 24.0 g of a target polymer (corresponding to formula (2-2), hereinafter abbreviated to pDPA-HDPA-EHA).

The pDPA-HDPA-EHA has a weight average molecular weight Mw of 10,500 and a polydispersity Mw/Mn of 3.10, which were measured by GPC in terms of polystyrene.

Next, 1.00 g of this obtained novolac resin and 0.001 g of a surfactant (manufactured by DIC Corporation, product name: MEGAFAC [trade name] R-30N, a fluorochemical surfactant) were dissolved into 3.45 g of propylene glycol monomethylether and 8.06 g of propylene glycol monomethylether acetate to prepare a resist underlayer film-forming composition.

### Example 3

To a 100-mL four-necked flask, diphenylamine (14.85 g, 0.088 mol, manufactured by Tokyo Chemical Industry Co., Ltd.), 1,1,1-tris(4-hydroxyphenyl) ethane (8.96 g, 0.029 mol), 2-ethylhexyl aldehyde (15.01 g, 0.117 mol, manufactured by Tokyo Chemical Industry Co., Ltd.), and propylene glycol monomethylether acetate (41 g, manufactured by Kanto Chemical Co., Inc.) were fed, added with methansulfonic acid (2.25 g, 0.023 mol, manufactured by Tokyo Chemical Industry Co., Ltd.) to be stirred together, and were heated to 130° C. to be dissolved, so that polymerization was started. The content of the flask cooled to room temperature 19 hours thereafter, and added with propylene glycol monomethylether acetate (55 g, manufactured by Kanto Chemical Co., Inc.) to be diluted, and then re-precipitated using a mixed solvent of methanol (1,900 g, manufactured by Kanto Chemical Co., Inc.) and ultrapure water (800 g) to obtain precipitate. The obtained precipitate was filtered and dried by a vacuum dryer at 80° C. for 24 hours to obtain 29.4 g of a target polymer (corresponding to formula (2-3), hereinafter abbreviated to pDPA-THPE-EHA).

The pDPA-THPE-EHA has a weight average molecular weight Mw of 4,200 and a polydispersity Mw/Mn of 1.91, which were measured by GPC in terms of polystyrene.

Next, 1.00 g of this obtained novolac resin and 0.001 g of a surfactant (manufactured by DIC Corporation, product name: MEGAFAC [trade name] R-30N, a fluorochemical surfactant) were dissolved into 3.45 g of propylene glycol monomethylether and 8.06 g of propylene glycol monomethylether acetate to prepare a resist underlayer film-forming composition.

### Example 4

To a 100-mL four-necked flask, N-phenyl-1-naphthylamine (14.57 g, 0.066 mol, manufactured by Tokyo Chemical Industry Co., Ltd.), 2-ethylhexyl aldehyde (8.49 g, 0.066 mol, manufactured by Tokyo Chemical Industry Co., Ltd.), and butyl cellosolve (25 g, manufactured by Kanto Chemical Co., Inc.) were fed, added with trifluoromethanesulfonic acid (2.06 g, 0.0014 mol, manufactured by Tokyo Chemical Industry Co., Ltd.) to be stirred together, and were heated to 150° C. to be dissolved, so that polymerization was started. The content of the flask cooled to room temperature 30 minutes thereafter, added with THE (10 g, manufactured by Kanto Chemical Co., Inc.) to be diluted, and re-precipitated into methanol (700 g, manufactured by Kanto Chemical Co., Inc.) to obtain precipitate. The obtained precipitate was filtered and dried by a vacuum dryer at 80° C. for 24 hours to obtain 15.0 g of a target polymer (corresponding to formula (2-4), hereinafter abbreviated to pNP1NA-EHA).

The pNP1NA-EHA has a weight average molecular weight Mw of 2,100 and a polydispersity Mw/Mn of 1.39, which were measured by GPC in terms of polystyrene.

Next, 1.00 g of this obtained novolac resin, 0.25 g of 3,3′,5,5′-tetramethoxymethyl-4,4′-bisphenol (trade name: TMOM-BP, manufactured by HONSHU CHEMICAL INDUSTRY CO., LTD.) as a crosslinking agent, 0.025 g of p-phenol sulfonic acid pyridine salt as a crosslinking catalyst, and 0.001 g of a surfactant (manufactured by DIC were dissolved into 4.42 g of propylene glycol monomethylether and 10.30 g of propylene glycol monomethylether acetate to prepare a resist underlayer film-forming composition.

### Example 5

To a 100-mL four-necked flask, N-phenyl-2-naphthylamine (14.53 g, 0.066 mol, manufactured by Tokyo Chemical Industry Co., Ltd.), 2-ethylhexyl aldehyde (8.50 g, 0.066 mol, manufactured by Tokyo Chemical Industry Co., Ltd.), and butyl cellosolve (25 g, manufactured by Kanto Chemical Co., Inc.) were fed, added with trifluoromethanesulfonic acid (2.00 g, 0.0013 mol, manufactured by Tokyo Chemical Industry Co., Ltd.) to be stirred together, and were heated to 150° C. to be dissolved, so that polymerization was started. The content of the flask cooled to room temperature 6 hours thereafter, and added with THF (10 g, manufactured by Kanto Chemical Co., Inc.) to be diluted, and then re-precipitated into methanol (700 g, manufactured by Kanto Chemical Co., Inc.) to obtain precipitate. The obtained precipitate was filtered and dried by a vacuum dryer at 80° C. for 24 hours to obtain 19.0 g of a target polymer (corresponding to formula (2-5), hereinafter abbreviated to pNP2NA-EHA).

The pNP2NA-EHA has a weight average molecular weight Mw of 1,300 and a polydispersity Mw/Mn of 1.36, which were measured by GPC in terms of polystyrene.

Next, 1.00 g of this obtained novolac resin, 0.25 g of 3,3′,5,5′-tetramethoxymethyl-4,4′-bisphenol (trade name: TMOM-BP, manufactured by HONSHU CHEMICAL INDUSTRY CO., LTD.) as a crosslinking agent, 0.025 g of p-phenol sulfonic acid pyridine salt as a crosslinking catalyst, and 0.001 g of a surfactant (manufactured by DIC Corporation, product name: MEGAFAC [trade name] R-30N, a fluorochemical surfactant) were dissolved into 4.42 g of propylene glycol monomethylether and 10.30 g of propylene glycol monomethylether acetate to prepare a resist underlayer film-forming composition.

### Example 6

To a 100-mL four-necked flask, N-phenyl-1-naphthylamine (15.69 g, 0.072 mol, manufactured by Tokyo Chemical Industry Co., Ltd.), 2-ethylbutyl aldehyde (7.20 g, 0.072 mol, manufactured by Tokyo Chemical Industry Co., Ltd.), and butyl cellosolve (25 g, manufactured by Kanto Chemical Co., Inc.) were fed, added with trifluoromethanesulfonic acid (2.17 g, 0.0014 mol, manufactured by Tokyo Chemical Industry Co., Ltd.) to be stirred together, and were heated to 150° C. to be dissolved, so that polymerization was started. The content of the flask cooled to room temperature 30 minutes thereafter, added with THE (10 g, manufactured by Kanto Chemical Co., Inc.) to be diluted, and re-precipitated into methanol (700 g, manufactured by Kanto Chemical Co., Inc.) to obtain precipitate. The obtained precipitate was filtered and dried by a vacuum dryer at 80° C. for 24 hours to obtain 15.5 g of a target polymer (corresponding to formula (2-6), hereinafter abbreviated to pNP1NA-EBA).

The pNP1NA-EBA has a weight average molecular weight Mw of 2,200 and a polydispersity Mw/Mn of 1.62, which were measured by GPC in terms of polystyrene. Next, 1.00 g of this obtained novolac resin, 0.25 g of 3,3′,5,5′-tetramethoxymethyl-4,4′-bisphenol (trade name: TMOM-BP, manufactured by HONSHU CHEMICAL INDUSTRY CO., LTD.) as a crosslinking agent, 0.025 g of p-phenol sulfonic acid pyridine salt as a crosslinking catalyst, and 0.001 g of a surfactant (manufactured by DIC Corporation, product name: MEGAFAC [trade name] R-30N, a fluorochemical surfactant) were dissolved into 4.42 g of propylene glycol monomethylether and 10.30 g of propylene glycol monomethylether acetate to prepare a resist underlayer film-forming composition.

### Example 7

To a 100-mL four-necked flask, N-phenyl-1-naphthylamine (15.74 g, 0.072 mol, manufactured by Tokyo Chemical Industry Co., Ltd.), 2-methyl-valeraldehyde (7.17 g, 0.072 mol, manufactured by Tokyo Chemical Industry Co., Ltd.), and butyl cellosolve (25 g, manufactured by Kanto Chemical Co., Inc.) were fed, added with trifluoromethanesulfonic acid (2.15 g, 0.0014 mol, manufactured by Tokyo Chemical Industry Co., Ltd.) to be stirred together, and were heated to 150° C. to be dissolved, so that polymerization was started. The content of the flask cooled to room temperature 30 minutes thereafter, added with THF (10 g, manufactured by Kanto Chemical Co., Inc.) to be diluted, and re-precipitated into methanol (700 g, manufactured by Kanto Chemical Co., Inc.) to obtain precipitate. The obtained precipitate was filtered and dried by a vacuum dryer at 80° C. for 24 hours to obtain 17.7 g of a target polymer (corresponding to formula (2-7), hereinafter abbreviated to pNP1NA-MVA).

The pNP1NA-MVA has a weight average molecular weight Mw of 3,200 and a polydispersity Mw/Mn of 1.92, which were measured by GPC in terms of polystyrene.

Next, 1.00 g of this obtained novolac resin, 0.25 g of 3,3′,5,5′-tetramethoxymethyl-4,4′-bisphenol (trade name: TMOM-BP, manufactured by HONSHU CHEMICAL INDUSTRY CO., LTD.) as a crosslinking agent, 0.025 g of p-phenol sulfonic acid pyridine salt as a crosslinking catalyst, and 0.001 g of a surfactant (manufactured by DIC Corporation, product name: MEGAFAC [trade name] R-30N, a fluorochemical surfactant) were dissolved into 4.42 g of propylene glycol monomethylether and 10.30 g of propylene glycol monomethylether acetate to prepare a resist underlayer film-forming composition.

### Example 8

To a 200-mL four-necked flask, diphenylamine (30.23 g, 0.179 mol, manufactured by Tokyo Chemical Industry Co., Ltd.), 2-methylbutyraldehyde (19.20 g, 0.223 mol, manufactured by Tokyo Chemical Industry Co., Ltd.), and PGMEA (50 g, manufactured by Kanto Chemical Co., Inc.) were fed, added with methanesulfonic acid (0.53 g, 0.0055 mol, manufactured by Tokyo Chemical Industry Co., Ltd.) to be stirred together, and were heated to 120° C. to be dissolved, so that polymerization was started. The content of the flask cooled to room temperature 1 hour and 30 minutes thereafter, and a reaction solution was re-precipitated into methanol (1,500 g, manufactured by Kanto Chemical Co., Inc.) to obtain precipitate. The obtained precipitate was filtered and dried by a vacuum dryer at 80° C. for 24 hours to obtain 37.8 g of a target polymer (corresponding to formula (2-8), hereinafter abbreviated to pDPA-MBA).

The pDPA-MBA has a weight average molecular weight Mw of 2,900 and a polydispersity Mw/Mn of 1.95, which were measured by GPC in terms of polystyrene.

Next, 1.00 g of this obtained novolac resin, 0.25 g of 3,3′,5,5′-tetramethoxymethyl-4,4′-bisphenol (trade name: TMOM-BP, manufactured by HONSHU CHEMICAL INDUSTRY CO., LTD.) as a crosslinking agent, 0.025 g of p-phenol sulfonic acid pyridine salt as a crosslinking catalyst, and 0.001 g of a surfactant (manufactured by DIC were dissolved into 4.42 g of propylene glycol monomethylether and 10.30 g of propylene glycol monomethylether acetate to prepare a resist underlayer film-forming composition.

### Example 9

To a 200-mL four-necked flask, diphenylamine (32.45 g, 0.192 mol, manufactured by Tokyo Chemical Industry Co., Ltd.), isobutyraldehyde (17.26 g, 0.239 mol, manufactured by Tokyo Chemical Industry Co., Ltd.), and PGMEA (50 g, manufactured by Kanto Chemical Co., Inc.) were fed, added with methanesulfonic acid (0.29 g, 0.0030 mol, manufactured by Tokyo Chemical Industry Co., Ltd.) to be stirred together, and were heated to 120° C. to be dissolved, so that polymerization was started. The content of the flask cooled to room temperature 1 hour and 30 minutes thereafter, added with THF (20 g, manufactured by Kanto Chemical Co., Inc.) to be diluted, and re-precipitated into methanol (1,400 g, manufactured by Kanto Chemical Co., Inc.) to obtain precipitate. The obtained precipitate was filtered and dried by a vacuum dryer at 80° C. for 24 hours to obtain 29.4 g of a target polymer (corresponding to formula (2-9), hereinafter abbreviated to pDPA-IBA).

The pDPA-IBA has a weight average molecular weight Mw of 5,600 and a polydispersity Mw/Mn of 2.10, which were measured by GPC in terms of polystyrene.

Next, 1.00 g of this obtained novolac resin, 0.25 g of 3,3′,5,5′-tetramethoxymethyl-4,4′-bisphenol (trade name: TMOM-BP, manufactured by HONSHU CHEMICAL INDUSTRY CO., LTD.) as a crosslinking agent, 0.025 g of p-phenol sulfonic acid pyridine salt as a crosslinking catalyst, and 0.001 g of a surfactant (manufactured by DIC Corporation, product name: MEGAFAC [trade name] R-30N, a fluorochemical surfactant) were dissolved into 4.42 g of propylene glycol monomethylether and 10.30 g of propylene glycol monomethylether acetate to prepare a resist underlayer film-forming composition.

### Example 10

To a 100-mL four-necked flask, N-phenyl-1-naphthylamine (21.30 g, 0.097 mol, manufactured by Tokyo Chemical Industry Co., Ltd.), valeraldehyde (8.38 g, 0.097 mol), and butyl cellosolve (8.0 g, manufactured by Kanto Chemical Co., Inc.) were fed, added with trifluoromethanesulfonic acid (2.36 g, 0.016 mol, manufactured by Tokyo Chemical Industry Co., Ltd.) to be stirred together, and were heated to 150° C. to be dissolved, so that polymerization was started. The content of the flask cooled to room temperature 4 hours thereafter, and added with butyl cellosolve (12 g, manufactured by Kanto Chemical Co., Inc.) to be diluted, and then a reaction solution is re-precipitated using methanol (400 g, manufactured by Kanto Chemical Co., Inc.) to obtain precipitate. The obtained precipitate was filtered and dried by a vacuum dryer at 70° C. for 24 hours to obtain 12.3 g of a target polymer (corresponding to formula (2-10), hereinafter abbreviated to pNP1NA-VA).

The pNP1NA-VA has a weight average molecular weight Mw of 1,000 and a polydispersity Mw/Mn of 1.32, which were measured by GPC in terms of polystyrene.

Next, 1.00 g of this obtained novolac resin, 0.25 g of 3,3′,5,5′-tetramethoxymethyl-4,4′-bisphenol (trade name: TMOM-BP, manufactured by HONSHU CHEMICAL INDUSTRY CO., LTD.) as a crosslinking agent, 0.025 g of p-phenol sulfonic acid pyridine salt as a crosslinking catalyst, and 0.001 g of a surfactant (manufactured by DIC Corporation, product name: MEGAFAC [trade name] R-30N, a fluorochemical surfactant) were dissolved into 5.08 g of propylene glycol monomethylether and 11.85 g of propylene glycol monomethylether acetate to prepare a resist underlayer film-forming composition.

### Example 11

To a 100-mL four-necked flask, N-phenyl-1-naphthylamine (23.26 g, 0.106 mol, manufactured by Tokyo Chemical Industry Co., Ltd.), n-propyl aldehyde (6.20 g, 0.107 mol), and butyl cellosolve (8.0 g, manufactured by Kanto Chemical Co., Inc.) were fed, added with trifluoromethanesulfonic acid (2.56 g, 0.017 mol, manufactured by Tokyo Chemical Industry Co., Ltd.) to be stirred together, and were heated to 150° C. to be dissolved, so that polymerization was started. The content of the flask cooled to room temperature 4 hours thereafter, and added with butyl cellosolve (18 g, manufactured by Kanto Chemical Co., Inc.) to be diluted, and then a reaction solution is re-precipitated using methanol (400 g, manufactured by Kanto Chemical Co., Inc.) to obtain precipitate. The obtained precipitate was filtered and dried by a vacuum dryer at 70° C. for 24 hours to obtain 21.2 g of a target polymer (corresponding to formula (2-11), hereinafter abbreviated to pNP1NA-PrA).

The NP1NA-PrA has a weight average molecular weight Mw of 1,000 and a polydispersity Mw/Mn of 1.20, which were measured by GPC in terms of polystyrene.

Next, 1.00 g of this obtained NP1NA-PrA novolac resin, 0.25 g of 3,3′,5,5′-tetramethoxymethyl-4,4′-bisphenol (trade name: TMOM-BP, manufactured by HONSHU CHEMICAL INDUSTRY CO., LTD.) as a crosslinking agent, 0.025 g of p-phenol sulfonic acid pyridine salt as a crosslinking catalyst, and 0.001 g of a surfactant (manufactured by DIC Corporation, product name: MEGAFAC [trade name] R-30N, a fluorochemical surfactant) were dissolved into 6.77 g of propylene glycol monomethylether and 10.16 g of propylene glycol monomethylether acetate to prepare a resist underlayer film-forming composition.

### Example 12

To a 100-mL four-necked flask, 3-hydroxydiphenylamine (14.83 g, 0.080 mol, manufactured by Tokyo Chemical Industry Co., Ltd.), 2-ethylhexyl aldehyde (10.21 g, 0.080 mol, manufactured by Tokyo Chemical Industry Co., Ltd.), and butyl cellosolve (25 g, manufactured by Kanto Chemical Co., Inc.) were fed, added with trifluoromethanesulfonic acid (0.072 g, 0.0005 mol, manufactured by Tokyo Chemical Industry Co., Ltd.) to be stirred together, and were heated to 150° C. to be dissolved, so that polymerization was started. The content of the flask cooled to room temperature 1 hour thereafter, and added with THF (20 g, manufactured by Kanto Chemical Co., Inc.) to be diluted, and re-precipitated using a mixed solvent of methanol (500 g, manufactured by Kanto Chemical Co., Inc.), ultrapure water (500 g), and 30% ammonium water (50 g, manufactured by Kanto Chemical Co., Inc.) to obtain precipitate. The obtained precipitate was filtered and dried by a vacuum dryer at 80° C. for 24 hours to obtain 17.0 g of a target polymer (corresponding to formula (2-12), hereinafter abbreviated to pHDPA-EHA).

The pHDPA-EHA has a weight average molecular weight Mw of 6,200 and a polydispersity Mw/Mn of 3.17, which were measured by GPC in terms of polystyrene.

Next, 1.00 g of this obtained novolac resin, 0.25 g of 3,3′,5,5′-tetramethoxymethyl-4,4′-bisphenol (trade name: TMOM-BP, manufactured by HONSHU CHEMICAL INDUSTRY CO., LTD.) as a crosslinking agent, 0.025 g of pyridinium p-phenol sulfonic acid indicated by formula (5) as a crosslinking catalyst, and 0.001 g of a surfactant (manufactured by DIC Corporation, product name: MEGAFAC [trade name] R-30N, a fluorochemical surfactant) were dissolved into 4.42 g of propylene glycol monomethylether and 10.30 g of propylene glycol monomethylether acetate to prepare a resist underlayer film-forming composition.

### Example 13

To a 100-mL four-necked flask, N,N′-diphenylethylenediamine (11.57 g, 0.055 mol, manufactured by Tokyo Chemical Industry Co., Ltd.), 2-ethylhexyl aldehyde (8.34 g, 0.068 mol, manufactured by Tokyo Chemical Industry Co., Ltd.), and butyl cellosolve (20 g, manufactured by Kanto Chemical Co., Inc.) were fed, added with trifluoromethanesulfonic acid (0.11 g, 0.0007 mol, manufactured by Tokyo Chemical Industry Co., Ltd.) to be stirred together, and were heated to 150° C. to be dissolved, so that polymerization was started. The content of the flask cooled to room temperature 4 hours thereafter, and re-precipitated using a mixed solvent of methanol (650 g, manufactured by Kanto Chemical Co., Inc.) and 30% ammonium water (50 g, manufactured by Kanto Chemical Co., Inc.) to obtain precipitate. The obtained precipitate was filtered and dried by a vacuum dryer at 80° C. for 24 hours to obtain 15.0 g of a target polymer (corresponding to formula (2-13), hereinafter abbreviated to pDPEDA-EHA).

The pDPEDA-EHA has a weight average molecular weight Mw of 2,200 and a polydispersity Mw/Mn of 1.83, which were measured by GPC in terms of polystyrene.

Next, 1.00 g of this obtained novolac resin, 0.25 g of 3,3′,5,5′-tetramethoxymethyl-4,4′-bisphenol (trade name: TMOM-BP, manufactured by HONSHU CHEMICAL INDUSTRY CO., LTD.) as a crosslinking agent, 0.025 g of pyridinium p-phenol sulfonic acid indicated by formula (5) as a crosslinking catalyst, and 0.001 g of a surfactant (manufactured by DIC Corporation, product name: MEGAFAC [trade name] R-30N, a fluorochemical surfactant) were dissolved into 4.42 g of propylene glycol monomethylether and 10.30 g of propylene glycol monomethylether acetate to prepare a resist underlayer film-forming composition.

### Example 14

To a 100-mL four-necked flask, 2,2′-biphenol (14.15 g, 0.076 mol, manufactured by Tokyo Chemical Industry Co., Ltd.), 2-ethylhexyl aldehyde (9.73 g, 0.076 mol, manufactured by Tokyo Chemical Industry Co., Ltd.), and butyl cellosolve (25 g, manufactured by Kanto Chemical Co., Inc.) were fed, added with trifluoromethanesulfonic acid (1.16 g, 0.0077 mol, manufactured by Tokyo Chemical Industry Co., Ltd.) to be stirred together, and were heated to 150° C. to be dissolved, so that polymerization was started. The content of the flask cooled to room temperature 24 hours thereafter, and re-precipitated using a mixed solvent of ultrapure water (300 g) and 30% ammonium water (20 g, manufactured by Kanto Chemical Co., Inc.) to obtain precipitate. The obtained precipitate was filtered and dried by a vacuum dryer at 80° C. for 24 hours to obtain 13.5 g of a target polymer (corresponding to formula (2-14), hereinafter abbreviated to pBPOH-EHA).

The pBPOH-EHA has a weight average molecular weight Mw of 2,500 and a polydispersity Mw/Mn of 3.15, which were measured by GPC in terms of polystyrene.

Next, 1.00 g of this obtained novolac resin, 0.25 g of 3,3′,5,5′-tetramethoxymethyl-4,4′-bisphenol (trade name: TMOM-BP, manufactured by HONSHU CHEMICAL INDUSTRY CO., LTD.) as a crosslinking agent, 0.025 g of pyridinium p-phenol sulfonic acid indicated by formula (5) as a crosslinking catalyst, and 0.001 g of a surfactant (manufactured by DIC Corporation, product name: MEGAFAC [trade name] R-30N, a fluorochemical surfactant) were dissolved into 4.42 g of propylene glycol monomethylether and 10.30 g of propylene glycol monomethylether acetate to prepare a resist underlayer film-forming composition.

### Example 15

To a 100-mL four-necked flask, N,N′-diphenyl-1,4-phenylenediamine (16.24 g, 0.062 mol, manufactured by Tokyo Chemical Industry Co., Ltd.), 2-ethylhexyl aldehyde (8.00 g, 0.062 mol, manufactured by Tokyo Chemical Industry Co., Ltd.), and butyl cellosolve (25 g, manufactured by Kanto Chemical Co., Inc.) were fed, added with methanesulfonic acid (1.21 g, 0.013 mol, manufactured by Tokyo Chemical Industry Co., Ltd.) to be stirred together, and were heated to 120° C. to be dissolved, so that polymerization was started. The content of the flask cooled to room temperature 3 hours thereafter, and re-precipitated into methanol (700 g, manufactured by Kanto Chemical Co., Inc.) to obtain precipitate. The obtained precipitate was filtered and dried by a vacuum dryer at 80° C. for 24 hours to obtain 11.4 g of a target polymer (corresponding to formula (2-15), hereinafter abbreviated to pDPPDA-EHA).

The pDPPDA-EHA has a weight average molecular weight Mw of 4,200 and polydispersity Mw/Mn of 1.97, which were measured by GPC in terms of polystyrene.

Next, 1.00 g of this obtained novolac resin, 0.25 g of 3,3′,5,5′-tetramethoxymethyl-4,4′-bisphenol (trade name: TMOM-BP, manufactured by HONSHU CHEMICAL INDUSTRY CO., LTD.) as a crosslinking agent, 0.025 g of pyridinium p-phenol sulfonic acid indicated by formula (5) as a crosslinking catalyst, and 0.001 g of a surfactant (manufactured by DIC Corporation, product name: MEGAFAC [trade name] R-30N, a fluorochemical surfactant) were dissolved into 4.42 g of propylene glycol monomethylether and 10.30 g of propylene glycol monomethylether acetate to prepare a resist underlayer film-forming composition.

### Comparative Example 1

To a 300-mL four-necked flask, Diphenylamine (24.26 g, 0.143 mol, manufactured by Tokyo Chemical Industry Co., Ltd.), benzaldehyde (15.24 g, 0.144 mol, manufactured by Tokyo Chemical Industry Co., Ltd.), and butyl cellosolve (160 g, manufactured by Kanto Chemical Co., Inc.) were fed, added with para-toluene sulfonic acid (0.54 g, 0.0028 mol, manufactured by Tokyo Chemical Industry Co., Ltd.) to be stirred together, and were heated to 150° C. to be dissolved, so that polymerization was started. The content of the flask cooled to room temperature 15 hours thereafter, and added with THF (30 g, manufactured by Kanto Chemical Co., Inc.) to be diluted, and a reaction solution was re-precipitated using methanol (1,400 g, manufactured by Kanto Chemical Co., Inc.) to obtain precipitate. The obtained precipitate was filtered and dried by a vacuum dryer at 80° C. for 24 hours to obtain 15.4 g of target polymer (corresponding to formula (6), hereinafter abbreviated to pDPA-BA).

The pDPA-BA has a weight average molecular weight Mw of 6,100 and a polydispersity Mw/Mn of 2.21, which were measured by GPC in terms of polystyrene.

Next, 1.00 g of this obtained novolac resin, 0.25 g of 3,3′,5,5′-tetramethoxymethyl-4,4′-bisphenol (trade name: TMOM-BP, manufactured by HONSHU CHEMICAL INDUSTRY CO., LTD.) as a crosslinking agent, 0.025 g of p-phenol sulfonic acid pyridine salt as a crosslinking catalyst, and 0.001 g of a surfactant (manufactured by DIC Corporation, product name: MEGAFAC [trade name] R-30N, a fluorochemical surfactant) were dissolved into 4.42 g of propylene glycol monomethylether and 10.30 g of propylene glycol monomethylether acetate to prepare a resist underlayer film-forming composition.

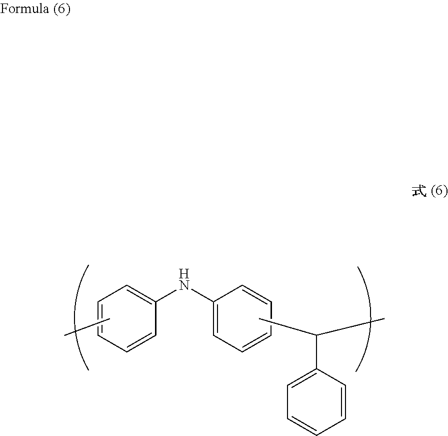

### [Optical Constant and Selective Ratio of Etching Rates]

The prepared resist underlayer film-forming compositions of Examples 1 to 15 and Comparative Example 1 were applied onto individual silicon wafers, and heated on a hot plate to form resist underlayer films. For baking conditions, the prepared resist underlayer film-forming compositions of Example 1, Example 4, Example 6, Example 7, Example 8, Example 9, Example 12, Example 14, and Example 15 were heated at 215° C. for one minute, the prepared resist underlayer film-forming compositions of Example 5, Example 10, Example 11, and Comparative Example 1 were heated at 250° C. for one minute, the prepared resist underlayer film-forming composition of Example 2 was heated at 300° C. for one minute, the prepared resist underlayer film-forming composition of Example 3 was heated at 340° C. for one minute, and the prepared resist underlayer film-forming composition of Example 13 was heated at 350° C. for one minute. Refractive index and attenuation coefficient of the above-described resist underlayer films at 193 nm were measured.

The refractive index and the attenuation coefficient were measured by using an ellipsometer (VUV-VASE) manufactured by J.A. Woollam Japan Corp.

Furthermore, a dry etching rate of each of the resist underlayer films formed by applying the prepared resist underlayer film-forming compositions of Examples 1 to 15 and Comparative Example 1 onto respective silicon wafers, and baking the applied compositions under the same baking conditions as described above, was compared with that of a resist film obtained from a resist solution manufactured by Sumitomo Chemical Co., Ltd. (product name: Sumi Resist PAR855). The dry etching rate was measured by using a dry etching apparatus manufactured by SAMCO Inc. (RIE-10NR), and dry etching rate was measured using CF4 gases.

Table 1 shows the refractive index of the resist underlayer films (n value), the attenuation coefficient (k value), and the ratio of dry etching rates (selective ratio of dry etching rates).

TABLE 1

| | Refractive | Attenuation | | Selective ratio |
|---|---|---|---|---|
| | index | coefficient | Wavelength | of dry etching |
| | (n value) | (k value) | (nm) | rates |
| Example 1 | 1.55 | 0.48 | 193 | 0.78 |
| Example 2 | 1.54 | 0.48 | 193 | 0.78 |
| Example 3 | 1.52 | 0.51 | 193 | 0.81 |
| Example 4 | 1.47 | 0.33 | 193 | 0.80 |
| Example 5 | 1.49 | 0.35 | 193 | 0.81 |
| Example 6 | 1.42 | 0.39 | 193 | 0.72 |
| Example 7 | 1.56 | 0.59 | 193 | 0.73 |
| Example 8 | 1.52 | 0.53 | 193 | 0.81 |
| Example 9 | 1.51 | 0.58 | 193 | 0.81 |
| Example 10 | 1.41 | 0.33 | 193 | 0.79 |
| Example 11 | 1.37 | 0.39 | 193 | 0.71 |
| Example 12 | 1.50 | 0.45 | 193 | 0.74 |
| Example 13 | 1.50 | 0.42 | 193 | 0.83 |
| Example 14 | 1.48 | 0.39 | 193 | 0.78 |
| Example 15 | 1.51 | 0.54 | 193 | 0.73 |
| Comparative | 1.52 | 0.84 | 193 | 0.78 |
| Example 1 | | | | |

According to the results of Table 1, the resist underlayer film obtained from the resist underlayer film-forming composition of the present invention has a proper reflection-preventive effect. Also, the resist underlayer film of the present invention has a high dry etching rate compared with the resist film. Thus, a substrate can be processed by applying a resist film onto a resist underlayer film that is obtained from the resist underlayer film-forming composition of the present invention, exposing and developing the resist film to form a resist pattern, and dry-etching the underlayer film and the resist film by using an etching gas or the like in accordance with the resist pattern.

### [Coating Test to a Stepped Substrate]

To evaluate step coverage, in SiO₂ substrates each having a film thickness of 200 nm, comparison was made in coating thickness between a dense pattern area (DENSE) thereof having a trench width of 50 nm and a pitch of 100 nm and an open area (OPEN) thereof in which no pattern is formed. After the resist underlayer film-forming compositions of Examples 1 to 15 and Comparative Example 1 were applied onto the individual substrates, the compositions of Example 1, Example 4, Example 6, Example 7, Example 8, Example 9, Example 12, Example 14, and Example 15 were baked at 215° C. for one minute, the compositions of Example 5, Example 10, Example 11, and Comparative Example 1 were baked at 250° C. for one minute, the composition of Example 2 was baked at 300° C. for one minute, the composition of Example 3 was baked at 340° C. for one minute, and the composition of Example 13 was baked at 350° C. for one minute so that the film thickness can be 150 nm. Step coverage of the substrates was observed using the Scanning Electron Microscope (S-4800) manufactured by Hitachi High-Technologies Corporation, so that a film thickness difference between a dense area (patterned part) and an open area (part without pattern) of a stepped substrate was measured (a difference in level of coating between the dense area and the open area, which is referred to as Bias) and the planarization property thereof was evaluated. Table 2 lists values of film thicknesses of the individual areas and a difference in level of coating. For the planarization property, the planarization becomes higher as a value of Bias becomes smaller.

TABLE 2

| | | | DENSE/OPEN |
|---|---|---|---|
| | DENSE | OPEN | difference in |
| | Film thickness | Film thickness | level of coating |
| | (nm) | (nm) | (nm) |
| Example 1 | 91 nm | 113 nm | 22 nm |
| Example 2 | 95 nm | 125 nm | 30 nm |
| Example 3 | 97 nm | 123 nm | 26 nm |
| Example 4 | 85 nm | 115 nm | 30 nm |
| Example 5 | 107 nm | 121 nm | 14 nm |
| Example 6 | 73 nm | 133 nm | 60 nm |
| Example 7 | 73 nm | 145 nm | 72 nm |
| Example 8 | 87 nm | 113 nm | 26 nm |
| Example 9 | 87 nm | 141 nm | 54 nm |
| Example 10 | 109 nm | 105 nm | 4 nm |
| Example 11 | 60 nm | 131 nm | 71 nm |
| Example 12 | 89 nm | 143 nm | 54 nm |
| Example 13 | 87 nm | 135 nm | 48 nm |
| Example 14 | 77 nm | 149 nm | 72 nm |
| Example 15 | 79 nm | 127 nm | 48 nm |
| Comparative | 71 nm | 149 nm | 78 nm |
| Example 1 | | | |

When step coverages of the stepped substrates are compared with each other, the results of Example 1 to Example 15 indicate that a difference in level of coating between the pattern area and the open area is smaller than the result of Comparative Example 1. This indicates that the individual resist underlayer films obtained from the resist underlayer film-forming compositions of Example 1 to Example 15 each have good planarization property.

In a method for forming a resist underlayer film, the method including applying the resist underlayer film-forming composition of the present invention onto a semiconductor substrate and baking the applied resist underlayer film-forming composition, a difference in level of the application between a part having the difference in level of the substrate and a part having no difference in level of the substrate is 3 nm to 73 nm, or 3 nm to 60 nm, or 3 nm to 30 nm. This provides a good planarization property.

### INDUSTRIAL APPLICABILITY

The resist underlayer film-forming composition of the present invention provides a high reflow property after being applied to a substrate and subjected to a baking process. This high reflow property enables the resist underlayer film-forming composition to be applied smoothly onto a stepped substrate to form a smooth film. Moreover, the resist underlayer film-forming composition has an adequate anti-reflective effect and has a high dry etching rate compared with the resist film. This high dry etching rate enables the substrate to be processed. Consequently, the resist underlayer film-forming composition of the present invention is effective as a resist underlayer film-forming composition.

1. A method for producing a semiconductor substrate coated with a resist underlayer film, the method comprising:
applying a resist underlayer film-forming composition with an enhanced thermal reflow property at the time of baking onto a semiconductor substrate having a difference in level, and
baking the applied resist underlayer film-forming composition to form a resist underlayer film having a difference in level of the applied surface between a part having the difference in level of the semiconductor substrate and a part having no difference in level of the semiconductor substrate of 3 nm to 73 nm,
wherein the resist underlayer film-forming composition comprises a novolac resin obtained by reacting an aromatic compound (A) with an aldehyde (B) having a formyl group bonded to a secondary carbon atom or tertiary carbon atom of a C₂₋₂₆ alkyl group for lowering a glass transition temperature (Tg) of the novolac resin.

2. The method for producing a semiconductor substrate according to claim 1, wherein the novolac resin comprises a unit structure of Formula (1): 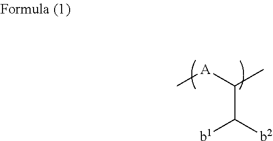
wherein:
A is a bivalence group derived from a C₆₋₄₀ aromatic compound;
b¹ is a C₁₋₁₆ alkyl group; and
b² is a hydrogen atom or a C₁₋₉ alkyl group.

3. The method for producing a semiconductor substrate according to claim 2, wherein A is the bivalent group derived from an aromatic compound comprising an amino group, a hydroxy group, or both an amino group and a hydroxy group.

4. The method for producing a semiconductor substrate according to claim 2, wherein A is the bivalent group derived from an aromatic compound comprising an arylamine compound, a phenol compound, or both an arylamine compound and a phenol compound.

5. The method for producing a semiconductor substrate according to claim 2, wherein A is the bivalent group derived from aniline, diphenylamine, phenylnaphthylamine, hydroxydiphenylamine, carbazole, phenol, N,N′-diphenylethylenediamine, N,N′-diphenyl-1,4-phenylenediamine, or a polynuclear phenol.

6. The method for producing a semiconductor substrate according to claim 5, wherein the polynuclear phenol is dihydroxybenzene, trihydroxybenzene, hydroxynaphthalene, dihydroxynaphthalene, trihydroxynaphthalene, tris(4-hydroxyphenyl) methane, tris(4-hydroxyphenyl) ethane, 2,2′-biphenol, or 1,1,2,2-tetrakis (4-hydroxyphenyl) ethane.

7. The method for producing a semiconductor substrate according to claim 1, wherein the novolac resin is a novolac resin comprising a unit structure of Formula (2): 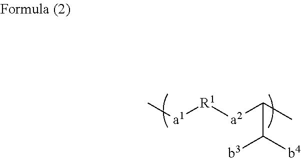
wherein:
each a¹ and a² is an optionally substituted benzene ring or naphthalene ring;
R¹ is a secondary amino group or a tertiary amino group, an optionally substituted C₁₋₁₀ divalent hydrocarbon group, an arylene group, or a divalent group to which these groups are arbitrarily bonded;
b³ is a C₁₋₁₆ alkyl group; and
b⁴ is a hydrogen atom or a C₁₋₉ alkyl group.

8. The method for producing a semiconductor substrate according to claim 1, wherein the resist underlayer film-forming composition further comprises an acid and/or an acid generator.

9. The method for producing a semiconductor substrate according to claim 1, wherein the resist underlayer film-forming composition further comprises a crosslinking agent.

10. A method for forming a resist pattern used in production of semiconductors, the method comprising:
applying a resist underlayer film-forming composition with an enhanced thermal reflow property at the time of baking onto a semiconductor substrate, and
baking the applied resist underlayer film-forming composition to form an underlayer film
wherein the resist underlayer film-forming composition comprises a novolac resin obtained by reacting an aromatic compound (A) with an aldehyde (B) having a formyl group bonded to a secondary carbon atom or tertiary carbon atom of a C₂₋₂₆ alkyl group for lowering a glass transition temperature (Tg) of the novolac resin.

11. A method for producing a semiconductor device, the method comprising:
forming an underlayer film from a resist underlayer film-forming composition on a semiconductor substrate;
forming a resist film on the underlayer film;
forming a resist pattern by irradiation with light or electron beams and development;
etching the underlayer film by using the formed resist pattern; and
processing the semiconductor substrate by using the patterned underlayer film,
wherein the resist underlayer film-forming composition comprises a novolac resin obtained by reacting an aromatic compound (A) with an aldehyde (B) having a formyl group bonded to a secondary carbon atom or tertiary carbon atom of a C₂₋₂₆ alkyl group for lowering a glass transition temperature (Tg) of the novolac resin.

12. A method for producing a semiconductor device, the method comprising:
forming an underlayer film from a resist underlayer film-forming composition on a semiconductor substrate;
forming a hard mask on the underlayer film;
forming a resist film on the hard mask;
forming a resist pattern by irradiation with light or electron beams and development;
etching the hard mask by using the formed resist pattern;
etching the underlayer film by using the patterned hard mask; and
processing the semiconductor substrate by using the patterned underlayer film,
wherein the resist underlayer film-forming composition comprises a novolac resin obtained by reacting an aromatic compound (A) with an aldehyde (B) having a formyl group bonded to a secondary carbon atom or tertiary carbon atom of a C₂₋₂₆ alkyl group for lowering a glass transition temperature (Tg) of the novolac resin.

13. The method for producing a semiconductor device according to claim 12, wherein the hard mask is formed by vapor deposition of an inorganic substance.
